(19) United States
(12) Patent Application Publication
(10) Pub. No.: US 2026/0206288 A1
(43) Pub. Date: Jul. 16, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chu-Yuan Hsu, Taichung City (TW); Jia-Chuan You, Taoyuan City (TW); Chia-Hao Chang, Hsinchu City (TW); Kuo-Cheng CHIANG, Hsinchu County (TW); Chih-Hao Wang, Hsinchu County (TW)

(73) Assignee: Taiwan Semiconductor Manufacturing Company, Ltd., Hsinchu (TW)

(21) Appl. No.: 19/026,208

(22) Filed: Jan. 16, 2025

(51) Int. Cl. H10D 84/01; H10D 64/01; H10D 84/83

(52) U.S. Cl. CPC H10D 84/0153; H10D 64/017; H10D 84/0135; H10D 84/833

(57) ABSTRACT

A method of forming a semiconductor device includes the following steps. Semiconductor tacks and dummy gate structures are formed. The dummy gate structures are arranged along a first direction to cover the stacks. Dielectric structures are formed between the dummy gate structures. The dummy gate structures are partially removed, to form first trenches between the dielectric structures. A lining layer is formed on the dummy gate structures exposed by the first trenches and dielectric structures. A second trench is formed in the lining layer along the first direction to expose the dummy gate structures. A gap-filling dielectric layer is formed over the lining layer to fill the first trenches. A recess is formed in a crossover region of the first and second trenches. The gap-filling dielectric layer, lining layer and dummy gate structures in the crossover region are removed, to form an opening. A wall structure is formed in the opening.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that may be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 17G illustrate varying views of intermediate steps during a process for forming a semiconductor device in accordance with some embodiments.

FIG. 18A is a perspective view of a semiconductor device in accordance with some embodiments, and FIG. 18B is a portion of a top view of FIG. 18A.

FIG. 19A is a perspective view of a semiconductor device in accordance with some embodiments, and FIG. 19B is a schematic cross-sectional view taken along the line I-I in FIG. 19A.

FIG. 20 illustrates a flowchart of a method of forming a semiconductor device according to some embodiments.

FIG. 21 illustrates a flowchart of a method of forming a semiconductor device according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description. Source/drain structure(s) may refer to a source or a drain, individually or collectively dependent upon the context.

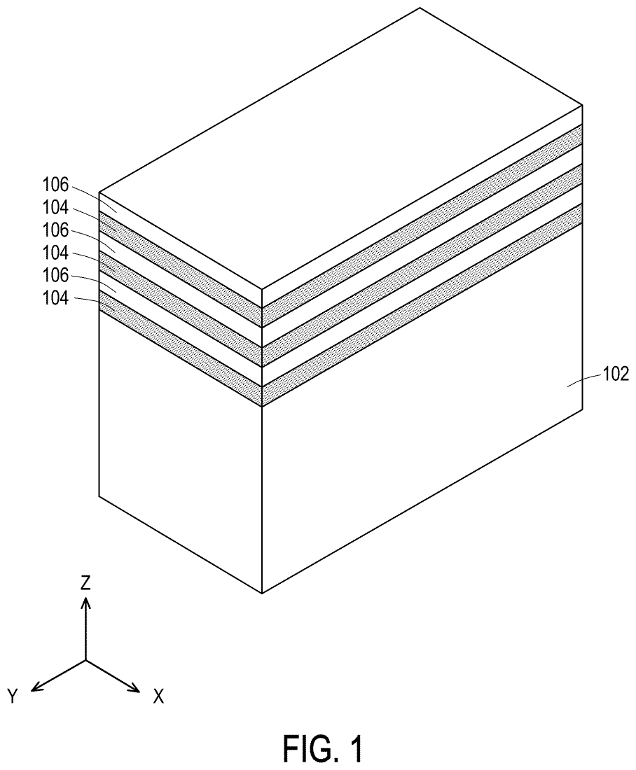

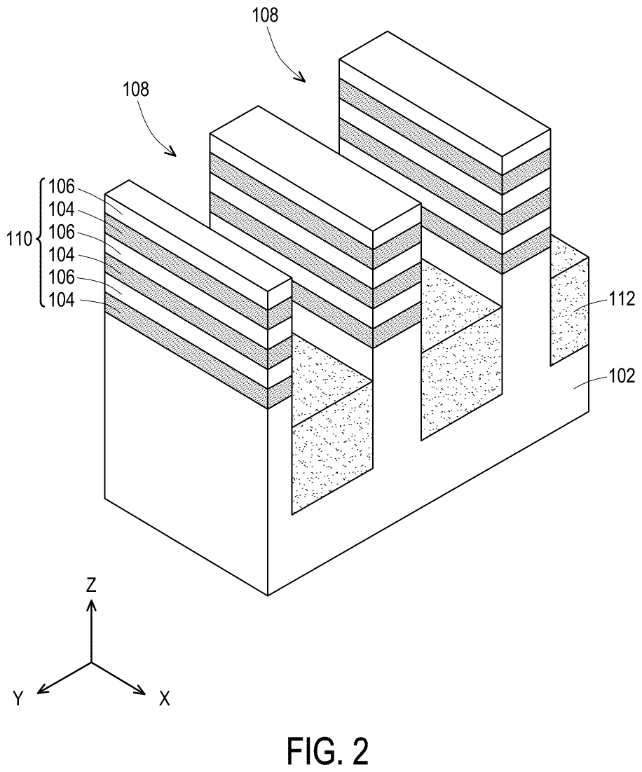

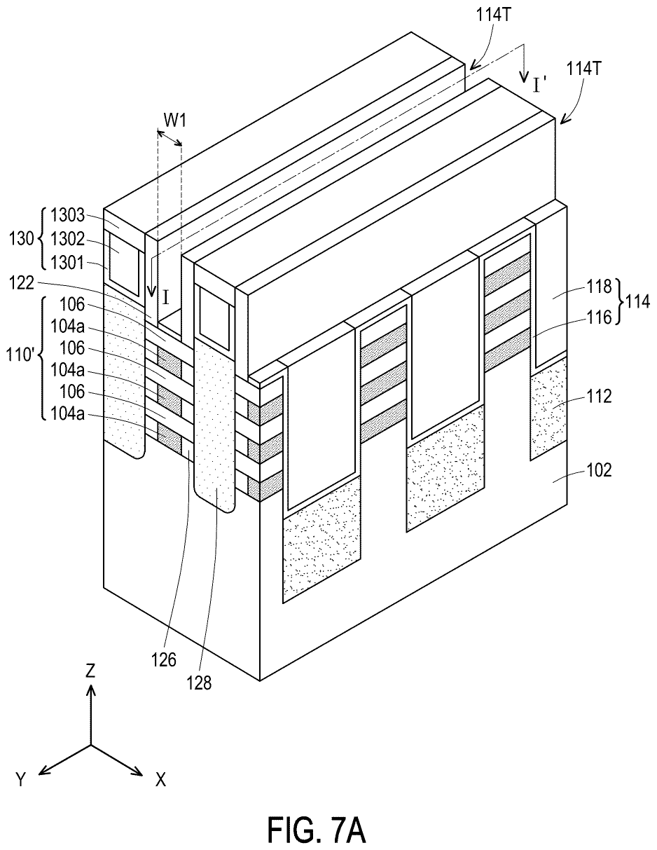

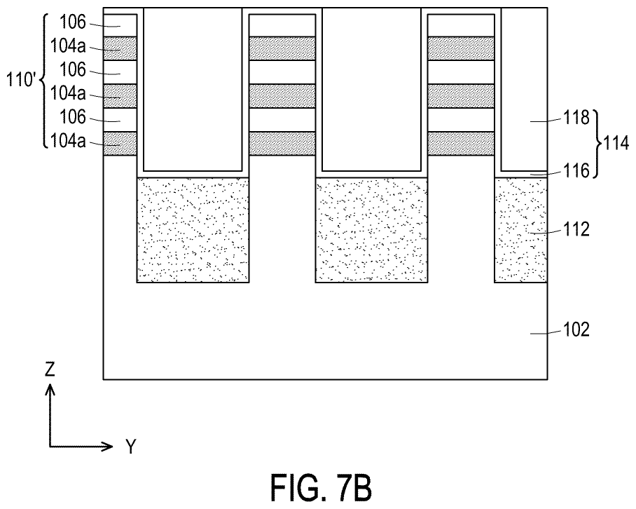

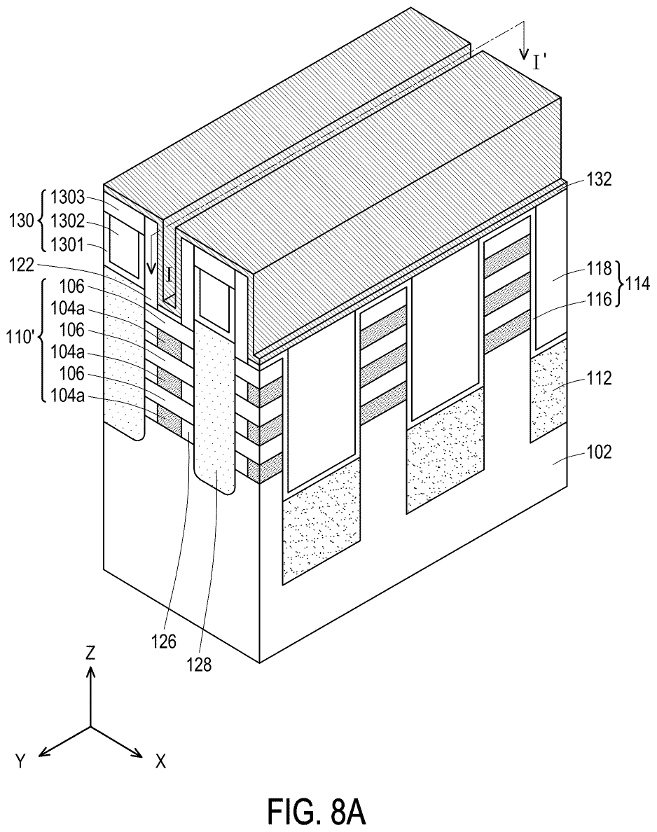

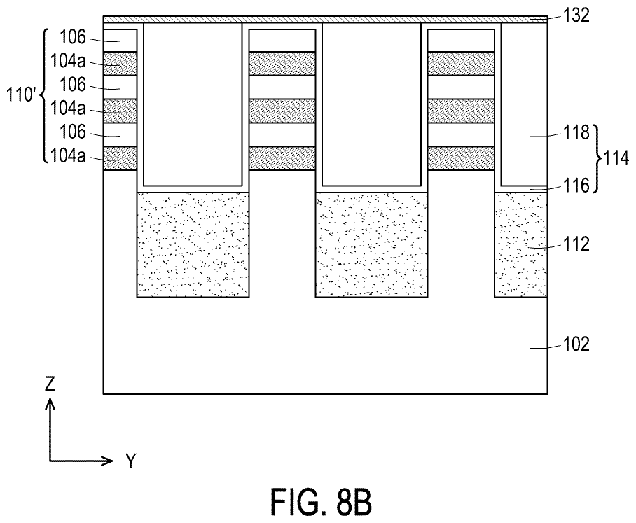

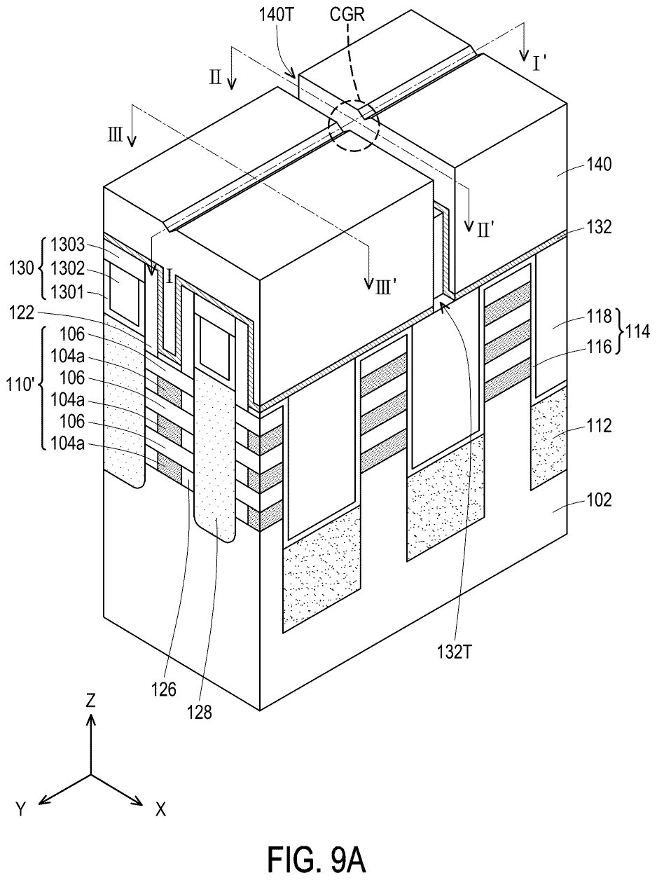

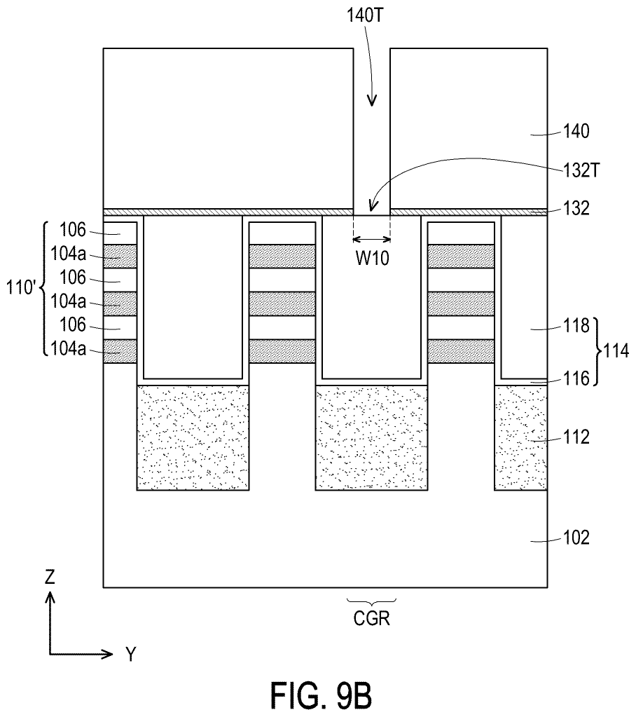

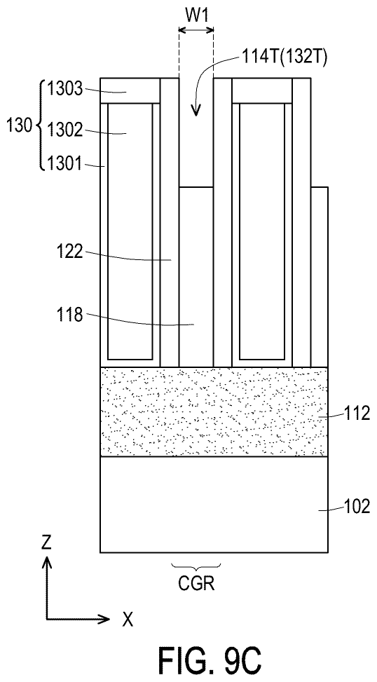

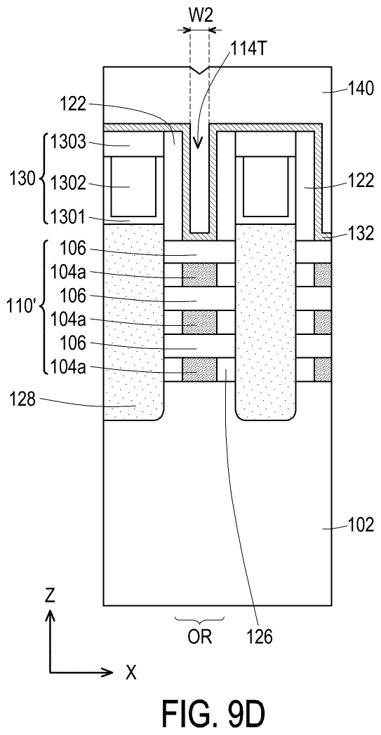

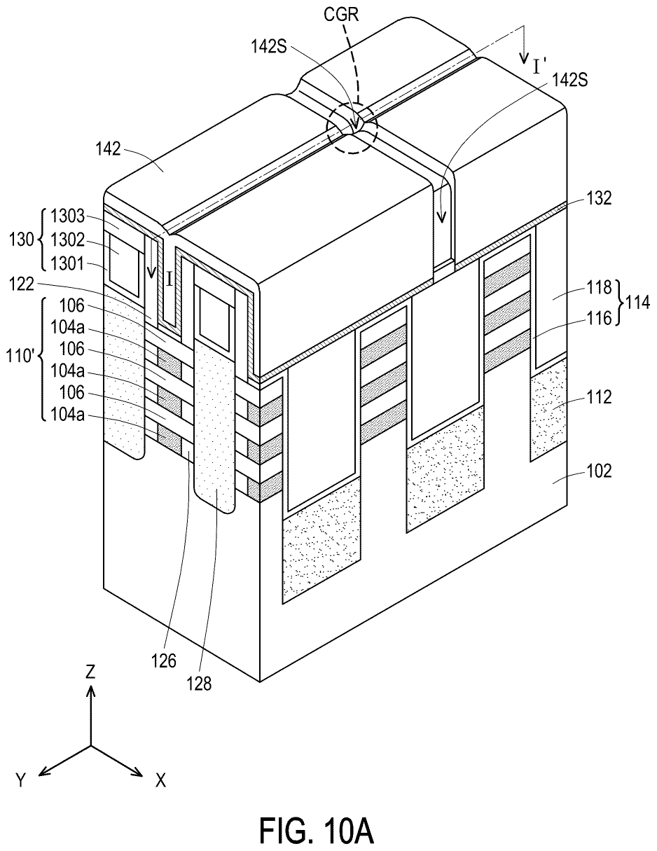

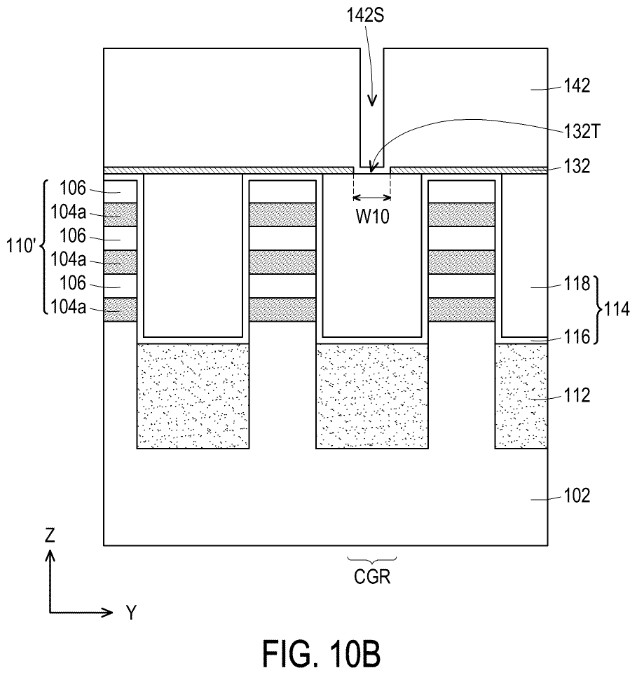

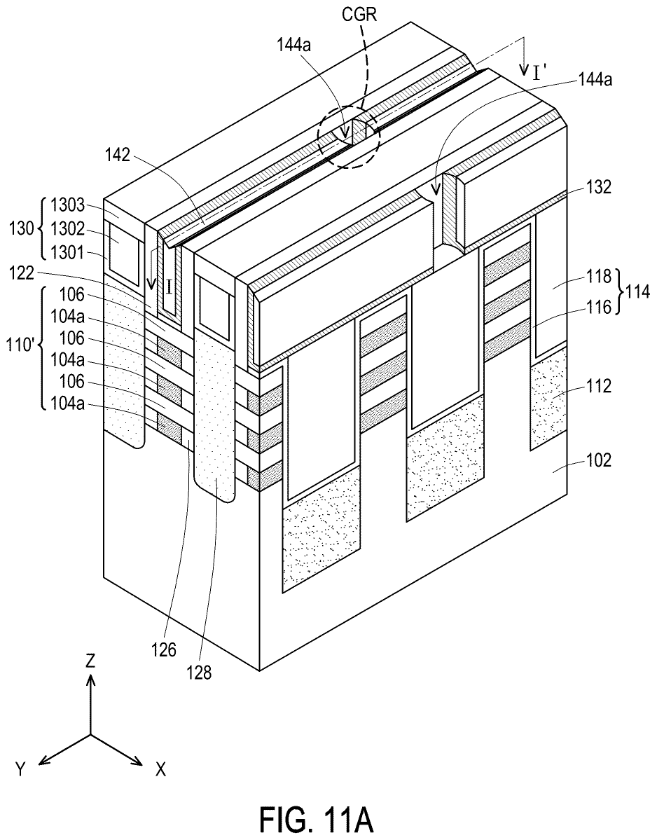

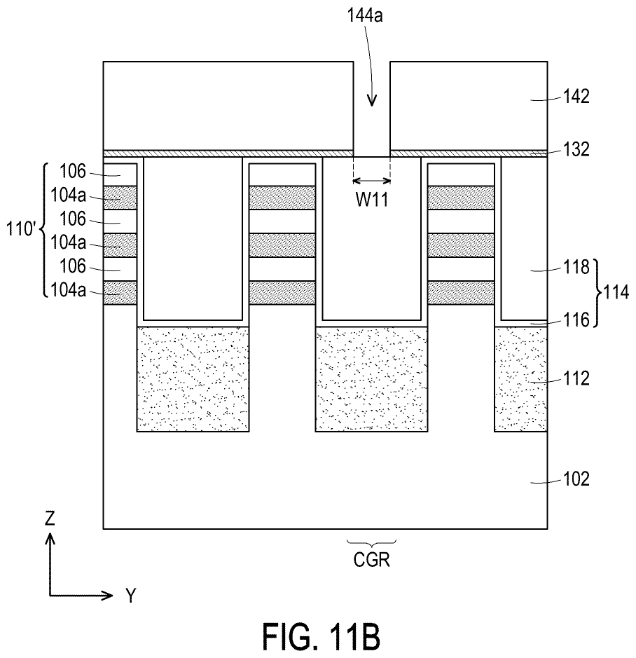

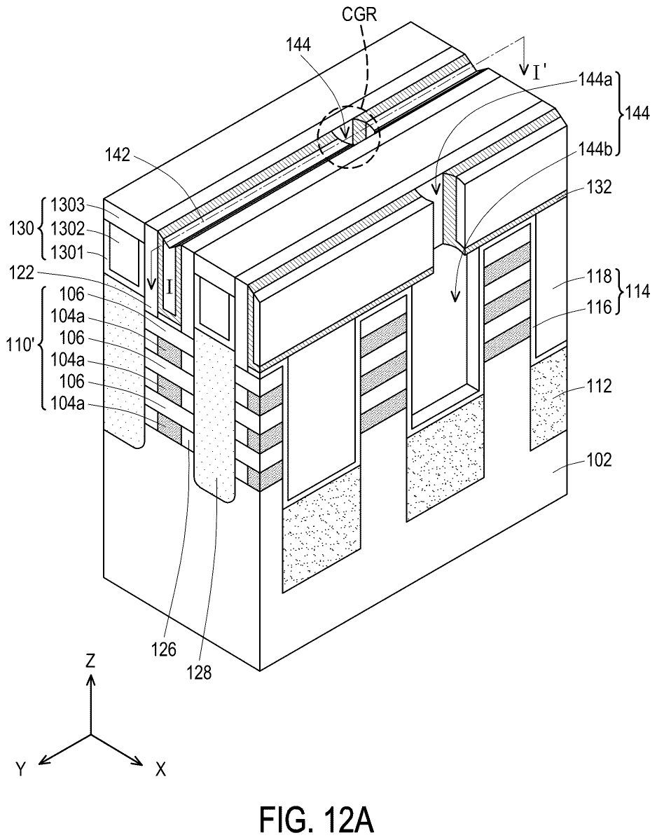

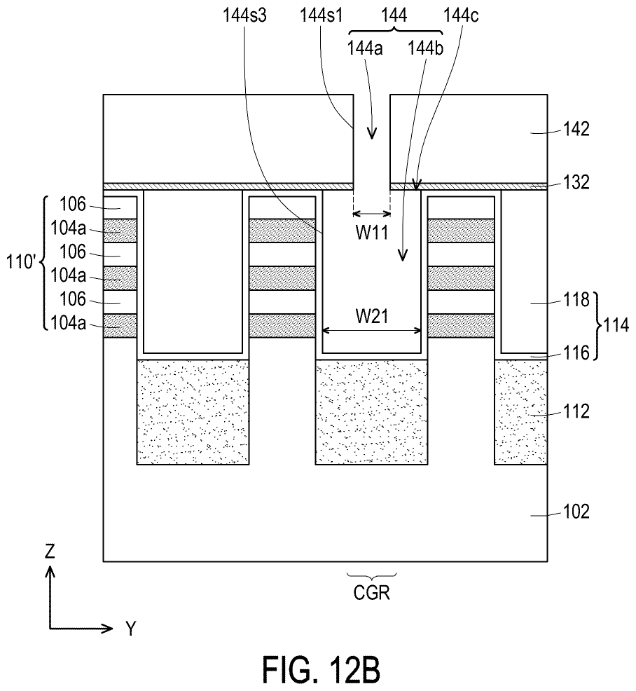

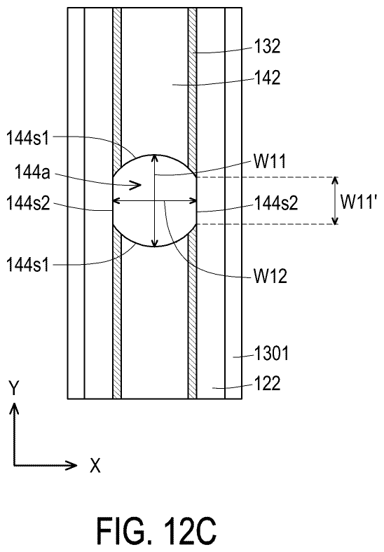

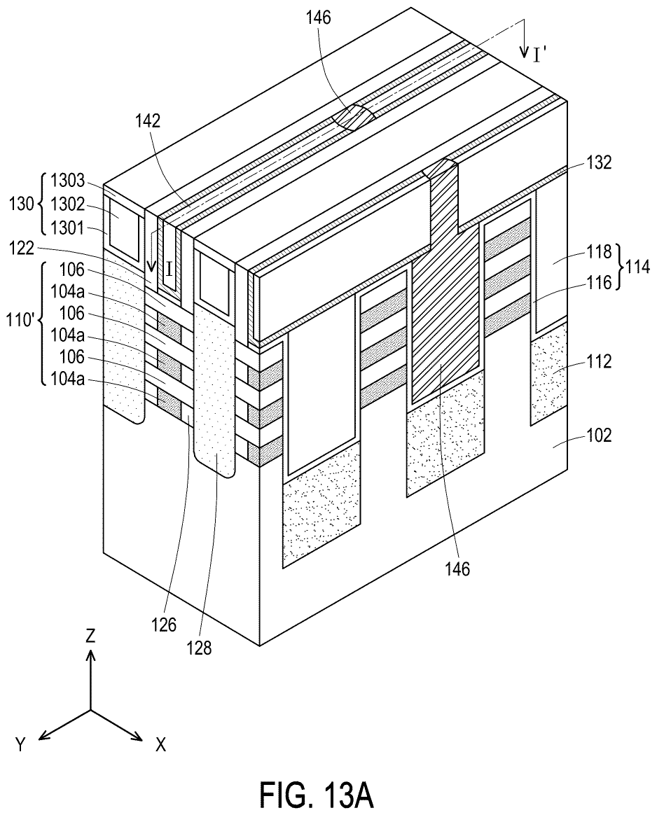

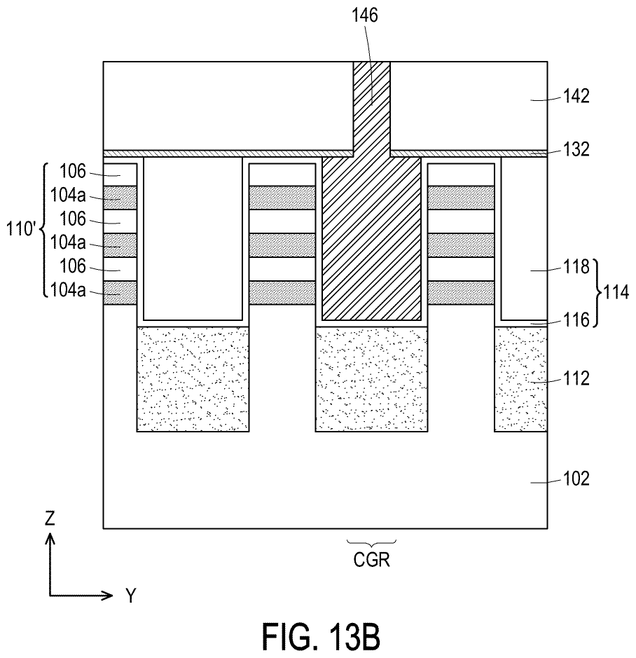

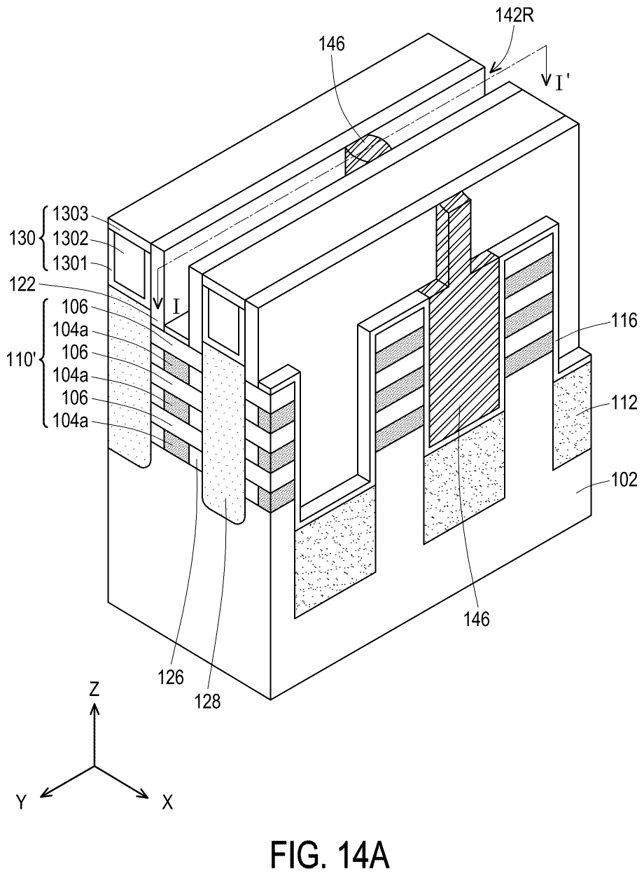

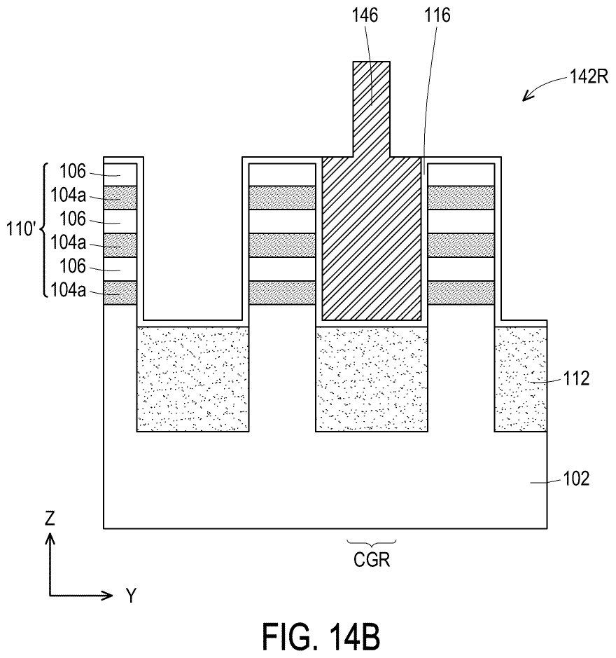

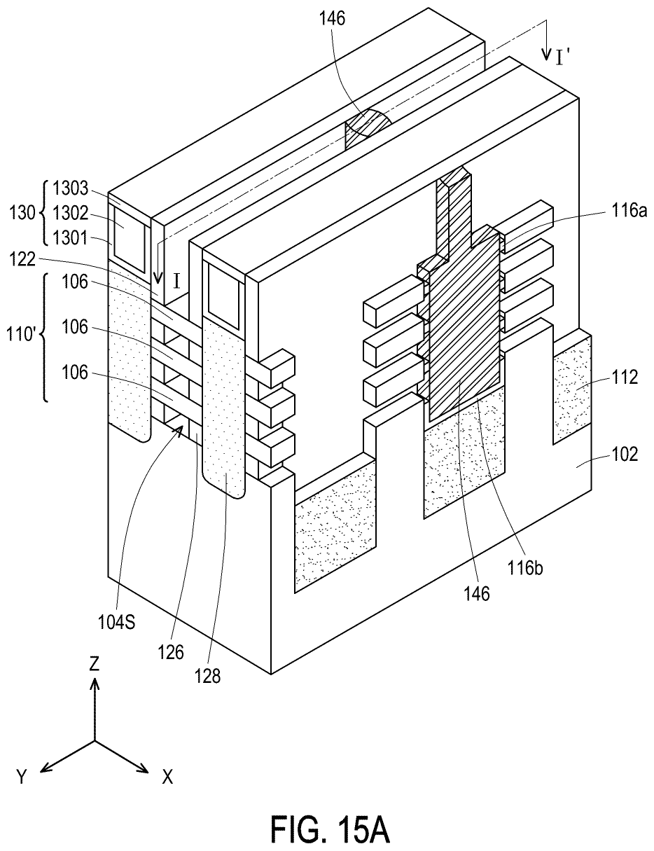

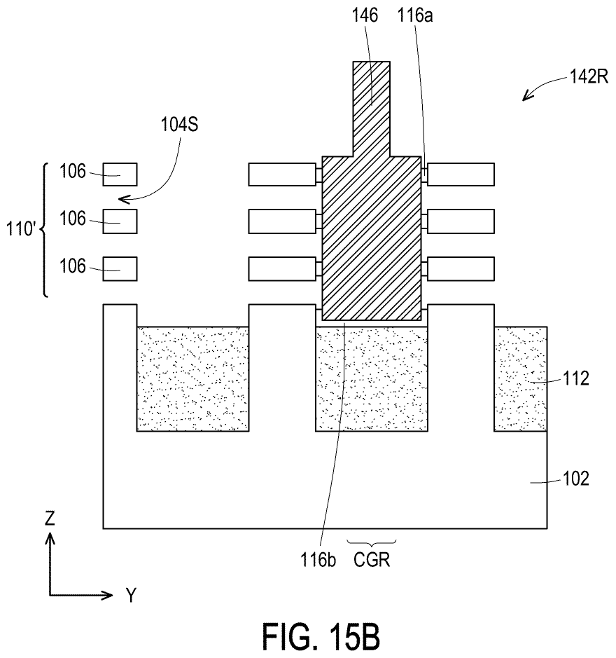

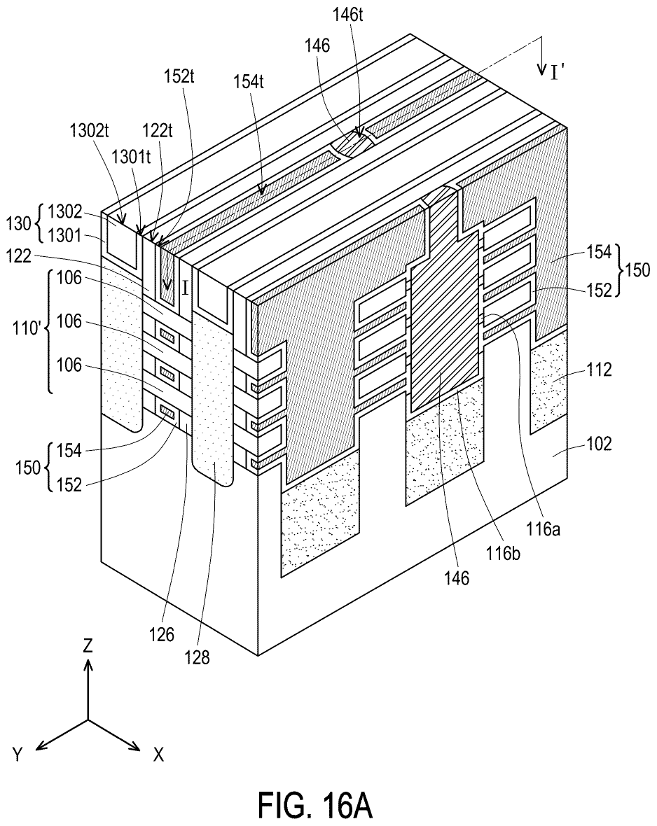

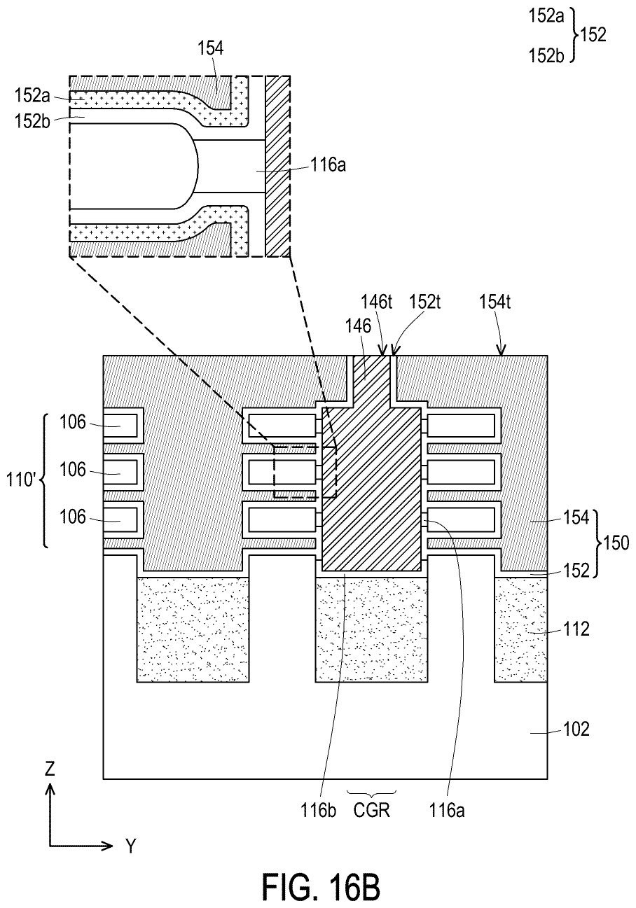

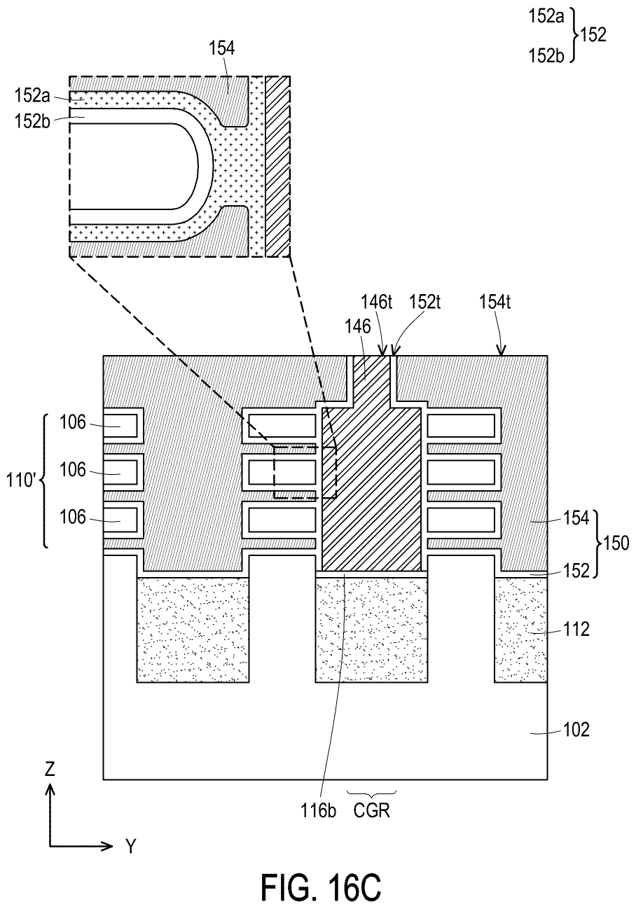

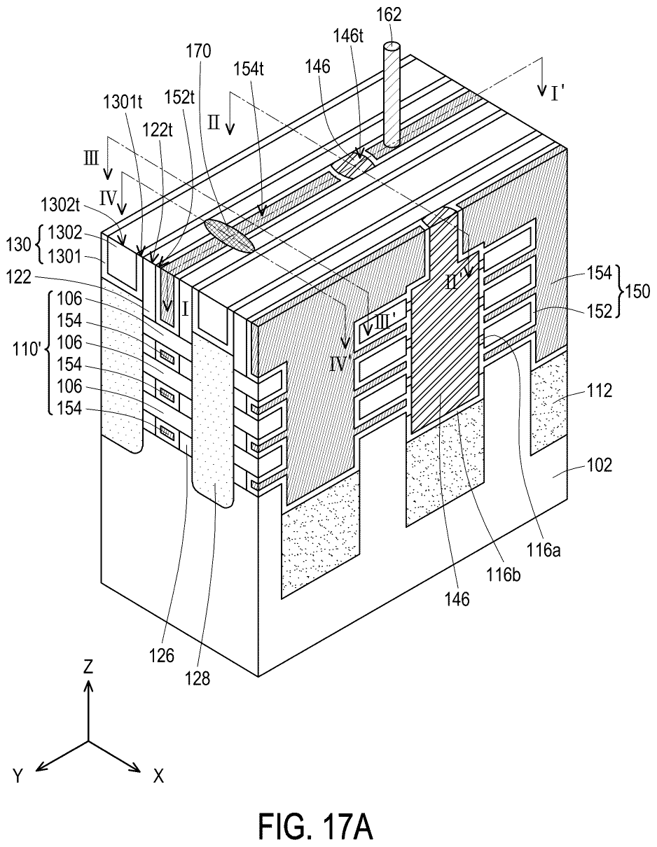

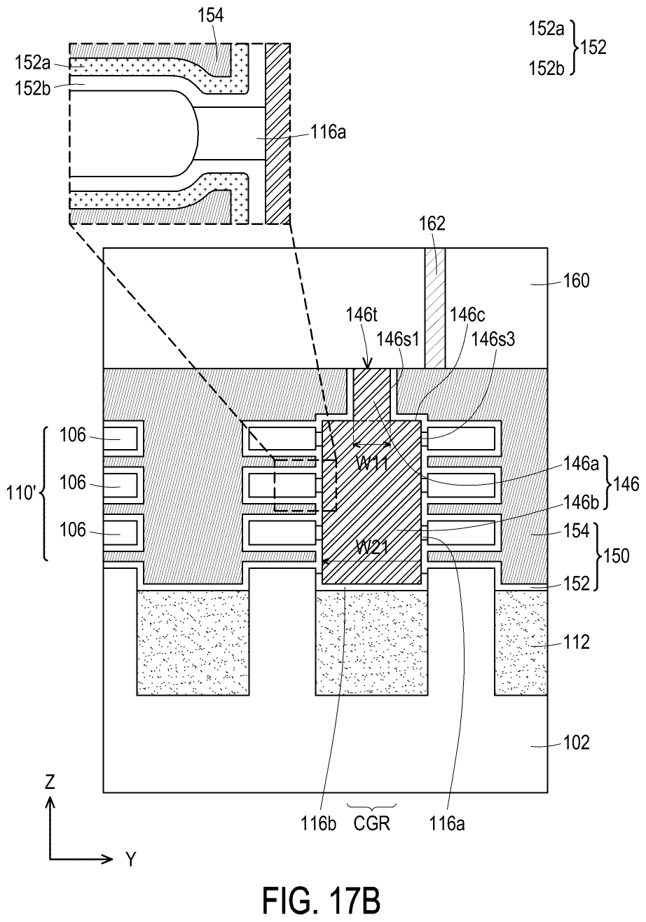

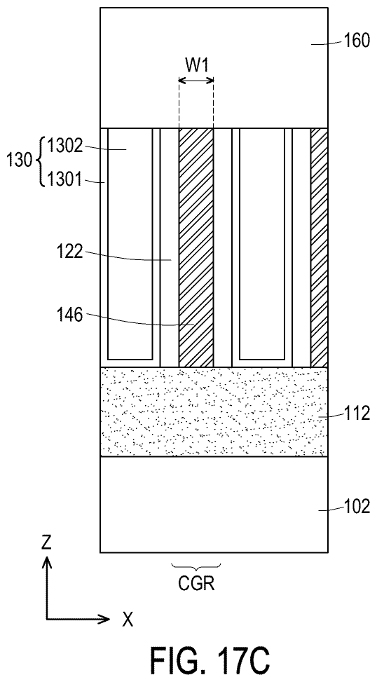

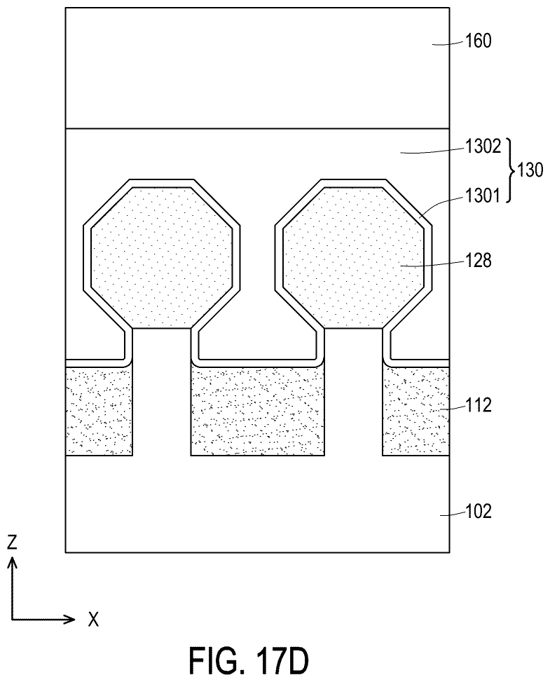

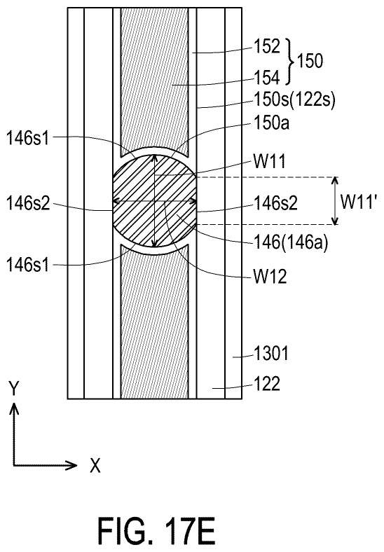

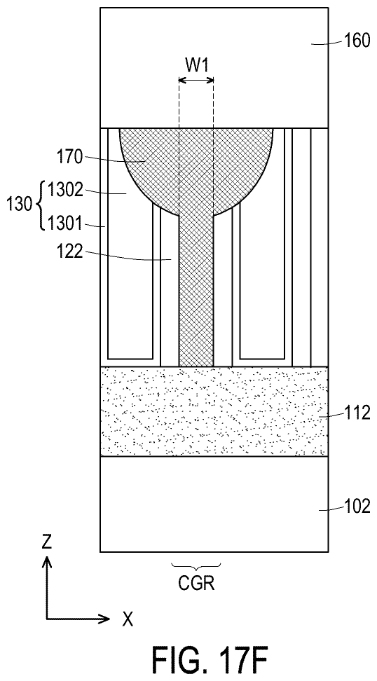

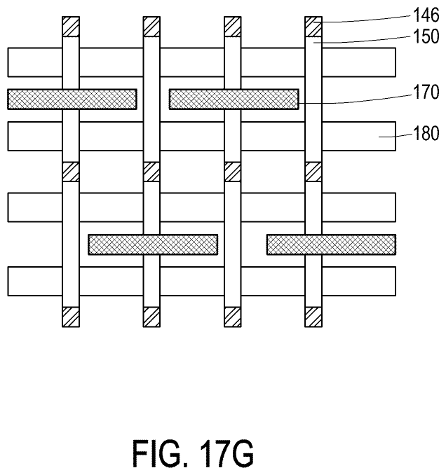

FIG. 1 to FIG. 17E illustrate varying views of intermediate steps during a process for forming a semiconductor device in accordance with some embodiments. FIG. 1 to FIG. 6, FIG. 7A, FIG. 8A, FIG. 9A, FIG. 10A, FIG. 11A, FIG. 12A, FIG. 13A, FIG. 14A, FIG. 15A, FIG. 16A and FIG. 17A are perspective views, FIG. 7B, FIG. 8B, FIG. 9B, FIG. 10B, FIG. 11B, FIG. 12B, FIG. 13B, FIG. 14B, FIG. 15B, FIG. 16B and FIG. 17B are schematic cross-sectional views taken along the line I-I in FIG. 7A, FIG. 8A, FIG. 9A, FIG. 10A, FIG. 11A, FIG. 12A, FIG. 13A, FIG. 14A, FIG. 15A, FIG. 16A and FIG. 17A, FIG. 9C and FIG. 17C are schematic cross-sectional views taken along the line II-II in FIG. 9A and FIG. 17A, FIG. 9D and FIG. 17D are schematic cross-sectional views taken along the line III-III in FIG. 9A and FIG. 17A, and FIG. 12C and FIG. 17E are top views of a portion of FIG. 12A and FIG. 17A. In FIG. 17A, an ILD structure 160 is omitted for clarity. FIG. 17F is a schematic cross-sectional view taken along the line IV-IV in FIG. 17A, and FIG. 17G is a top view of FIG. 17A.

Referring to FIG. 1, a stack of first semiconductor layers 104 and second semiconductor layers 106 may be formed on a semiconductor substrate 102. In some embodiments, the semiconductor substrate 102 includes a crystalline silicon substrate or a bulk silicon substrate (e.g., wafer). In some embodiments, the semiconductor substrate 102 is made of a suitable elemental semiconductor (e.g., germanium), a suitable compound semiconductor (e.g., gallium arsenide, silicon carbide, indium arsenide, or indium phosphide), a suitable alloy semiconductor (e.g., silicon germanium carbide, gallium arsenic phosphide, or gallium indium phosphide), and the like. In some embodiments, the semiconductor substrate 102 includes a semiconductor-on-insulator (SOI) substrate. The semiconductor substrate 102 may include various doped regions (not individually shown) doped with p-type or n-type dopants. The doped regions may be configured for an n-type field effect transistor (FET), or alternatively, configured for a p-type FET.

With continued reference to FIG. 1, the first semiconductor layers 104 and the second semiconductor layers 106 may be alternately stacked on each other to form a stack. The first semiconductor layers 104 and the second semiconductor layers 106 each extend along X direction and Y direction. The first semiconductor layers 104 may be also referred to as sacrificial layers since they will be removed in the subsequent process. In some embodiments, the bottommost one of the first semiconductor layers 104 is formed on the semiconductor substrate 102, with the remaining second and first semiconductor layers (106 and 104) alternately stacked thereon. However, the first semiconductor layer 104 or the second semiconductor layer 106 may be the bottommost layer (or the layer most proximate from the semiconductor substrate 102), and the first semiconductor layer 104 or the second semiconductor layer 106 may be the topmost layer (or the layer most distanced to the semiconductor substrate 102). In addition, the number of stacked semiconductor layers (e.g., 104 and 106) is not limited.

With continued reference to FIG. 1, the first semiconductor layers 104 and the second semiconductor layers 106 may have different materials (or compositions) that may provide for different oxidation rates and/or different etch selectivity between the layers. For example, the second semiconductor layers 106 are formed of the same material as the semiconductor substrate 102, while the first semiconductor layers 104 are formed of a different material which may be selectively removed with respect to the material of the semiconductor substrate 102 and the second semiconductor layers 106. In some embodiments, the material of the first semiconductor layers 104 includes silicon germanium, and the second semiconductor layers 106 include silicon. The second semiconductor layer 106 may be undoped or substantially dopant-free. However, the disclosure is not limited thereto, and other suitable material, or other combinations of materials for which selective etching is possible are contemplated within the scope of the disclosure. The second semiconductor layers 106 may be semiconductor nanosheets and may be considered as channel regions in the subsequent processes. The terms “semiconductor nanosheets,” “semiconductor nanostructures” and “channel regions” may be used interchangeably herein.

Referring to FIG. 2 and with reference to FIG. 1, a portion of the stack of first semiconductor layers 104 and second semiconductor layers 106 and the underlying portion of the semiconductor substrate 102 may be removed to form trenches 108 and a fin structure 110 between the trenches 108. Each trench 108 may be disposed between adjacent two of the fin structures 110. The trench 108 and the fin structure 110 may extend along X direction. In some embodiments, the fin structure 110 is formed by forming a mask layer (not shown) over the stack and patterning the stack of first semiconductor layers 104 and second semiconductor layers 106 and the underlying semiconductor substrate 102 by using the mask layer as a mask. The patterning is performed by lithography and etching, or other suitable techniques.

With continued reference to FIG. 2, a plurality of isolation structures 112 may be formed in lower portions of the trenches 108. The isolation structures 112 may be shallow trench isolation (STI) structures. For example, the isolation structures 112 extend at opposing sides of a lower portion of the semiconductor substrate 102. In some embodiments, each of the isolation structures 112 is disposed between adjacent two of the fin structures 110 and covers a sidewall of a lower portion of the respective fin structure 110. The isolation structures 112 may each be formed of one or more insulation material(s) (e.g., an oxide, a Si-based oxide (e.g., SiOC, SiOCN, or the like), a nitride, the like, any other suitable material(s), combinations thereof, etc.) which may electrically isolate neighboring fin structures 110 from each other.

The isolation structures 112 may be formed by initially depositing a layer of insulation material(s) in the respective trench 108 and recessing the layer of insulation material(s) using an acceptable etching process, such as one that is selective to the material(s) of the isolation structures 112. The fin structure 110 is protruded from the neighboring isolation structures 112. The top surfaces of the isolation structures 112 may be a flat surface, a curved (e.g., convex or concave) surface, or combinations thereof, depending on the etching process.

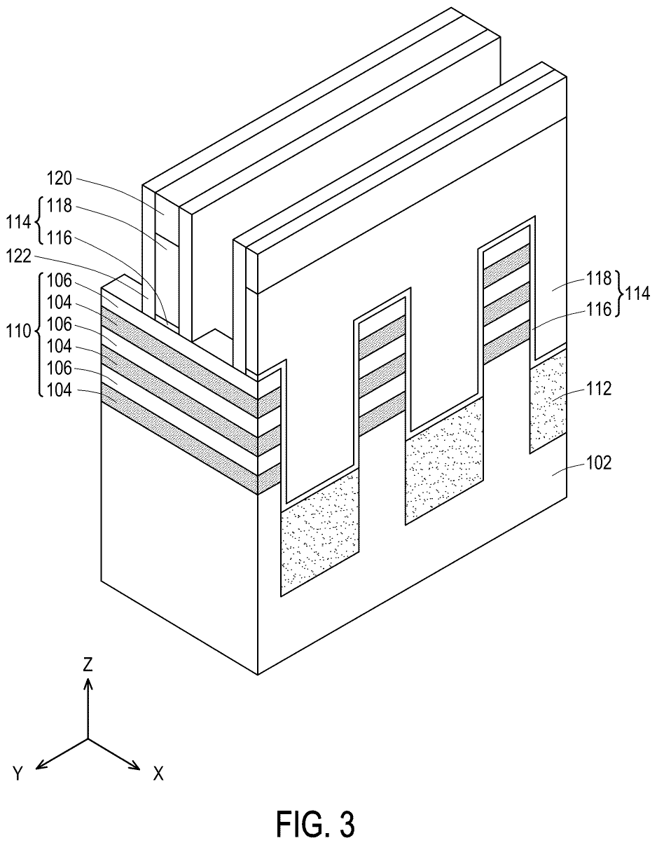

Referring to FIG. 3 and with reference to FIG. 2, a dummy gate structure 114 may be formed on the fin structures 110. The dummy gate structure 114 may also be formed in the trenches 108 and on the isolation structures 112. The dummy gate structure 114 may extend along Y direction. For example, the dummy gate structure 114 includes a dummy dielectric layer 116 covering the fin structures 110 and the isolation structures 112 and a dummy gate layer 118 formed on the dummy dielectric layer 116. In some embodiments, the dummy dielectric layer 116 covers the top surfaces of the isolation structures 112 and may extend between the dummy gate layer 118 and the isolation structures 112. The dummy dielectric layer 116 may be or include silicon oxide, silicon nitride, a combination thereof, or the like, and may be deposited or thermally grown according to acceptable techniques. The dummy gate layer 118 may be a conductive or non-conductive material and may be selected from a group including amorphous silicon, polysilicon, poly-crystalline silicon-germanium, metallic oxides, and metals, and may be formed by using physical vapor deposition (PVD), chemical vapor deposition (CVD), atomic layer deposition (ALD), sputtering, or other suitable techniques.

In some embodiments, a mask layer 120 is disposed on the dummy gate structure 114. The mask layer 120 may be a single mask layer or include multiple sublayers formed of different materials including silicon nitride, silicon oxynitride, or the like. For example, the mask layer 120 includes a first mask sublayer overlying the dummy gate structure 114 and a second mask sublayer overlying the first mask sublayer. In some embodiments, a material (not shown) of the dummy dielectric layer 116 and a material (not shown) of the dummy gate layer 118 are sequentially formed over the fin structures 110. Then, the mask layer 120 is formed on the material of the dummy gate layer 118, and the materials of the dummy dielectric layer 116 and the dummy gate layer 118 are patterned by using the mask layer 120 as a mask to form the dummy dielectric layer 116 and the dummy gate layer 118.

With continued reference to FIG. 3, a sidewall spacer layer 122 may then be formed on sidewalls of the mask layer 120 and the dummy gate structure 114. The sidewall spacer layer 122 may be a single layer or may include multiple sublayers formed of different materials including silicon oxide, silicon nitride, silicon oxynitride, or the like. The sidewall spacer layer 122 may be deposited by thermal oxidation or deposited by CVD, ALD, PVD, or the like. The sidewall spacer layer 122 may act to self-align subsequently formed source/drain (S/D) regions, as well as to protect sidewalls of the respective fin structure 110 during subsequent processing. In some embodiments, the sidewall spacer layer 122 is disposed on the sidewalls of the dummy gate structure 114 and extends to cover sidewalls of the mask layer 120.

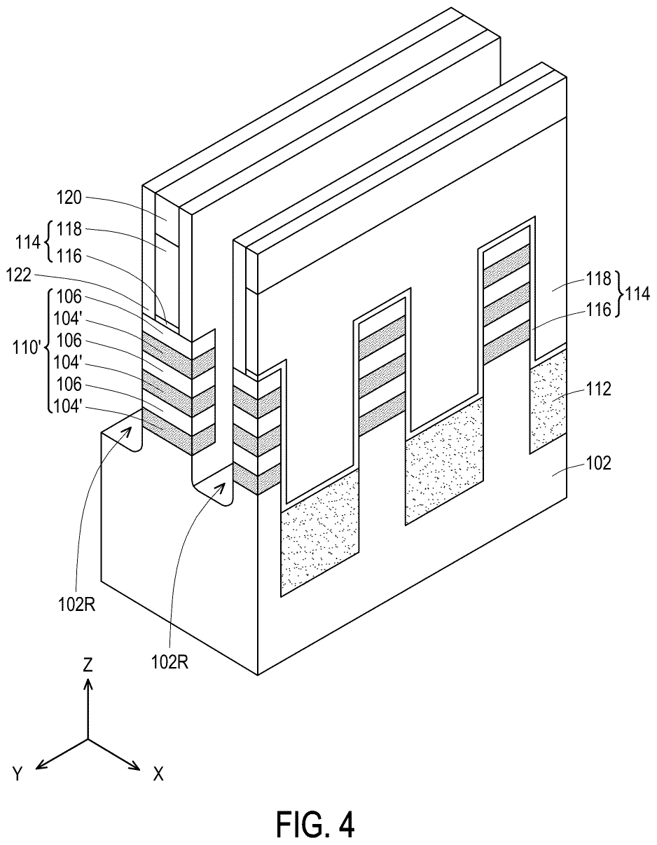

Referring to FIG. 4 and with reference to FIG. 3, a portion of the respective fin structure 110 and a portion of the semiconductor substrate 102 underlying the portion of the respective fin structure 110 may be removed to form recesses 102R. The S/D regions will be subsequently formed in the recesses 102R, and the recesses 102R may be referred to as S/D recesses. The recesses 102R may be formed by etching the underlying fin structures 110 and the underlying semiconductor substrate 102 using suitable etching processes (e.g., anisotropic etching or the like). The respective recess 102R may extend through the respective fin structure 110 to form a stack 110′. In some embodiments, outer sidewalls of the sidewall spacer layer 122 are substantially aligned with sidewalls of the stack 110′. In some embodiments, the respective recess 102R extends further into the underlying semiconductor substrate 102. The semiconductor substrate 102 may include fin portions which are bottom portions of the fin structure 110′ and recess portions laterally between the adjacent fin portions. A top surface of the recess portion may be a flat surface, a curved (e.g., concave) surface, or combinations thereof, depending on the etching process.

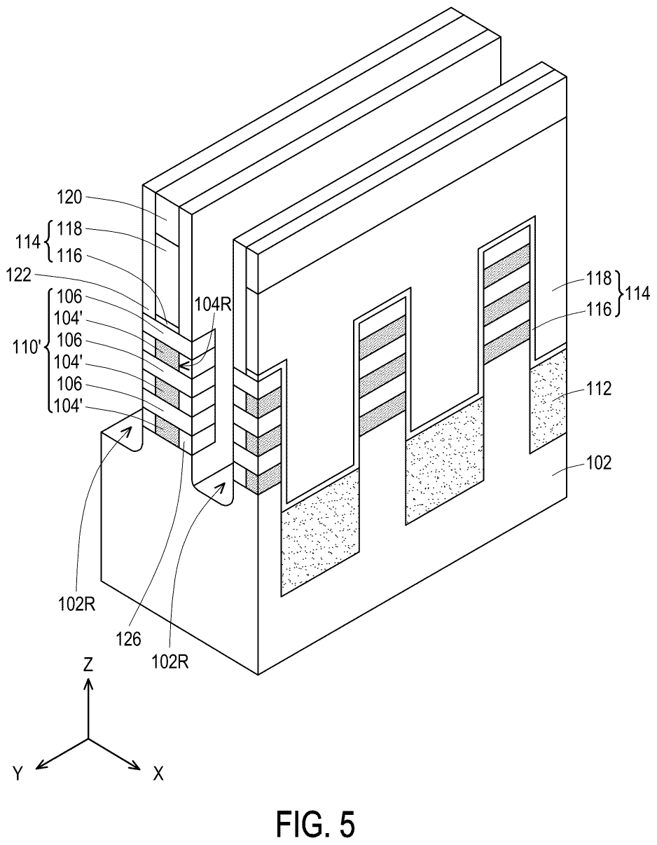

Referring to FIG. 5 and with reference to FIG. 4, lateral recesses 104R are formed at opposite sides of the first semiconductor layers 104a. For example, portions of the first semiconductor layers 104 exposed by the recesses 102R are removed in X direction, to form the etched first semiconductor layers 104a with the lateral recesses 104R. The first semiconductor layers 104 may be partially removed by using, e.g., isotropic etching processes or other suitable removal techniques. For example, the etchant of the selective etching process is chosen so that the portions of the first semiconductor layers 104 are removed to form the lateral recesses 104R, while the second semiconductor layers 106 remain substantially intact during the etching. The etched first semiconductor layer 104a may be laterally recessed from the sidewalls of the underlying (or overlying) second semiconductor layer 106. Although sidewalls of the etched first semiconductor layers 104a adjacent the lateral recesses 104R are illustrated as being straight in FIG. 5, the sidewalls of the etched first semiconductor layers 104a may be concave or convex.

Then, inner sidewall spacers 126 are formed in the lateral recesses 104R. For example, the inner sidewall spacers 126 are formed along the etched ends of each of the etched first semiconductor layers 104a and along respective ends of each of the etched first semiconductor layers 104a and the second semiconductor layers 106. The inner sidewall spacers 126 may be formed of silicon nitride, silicon carbon-nitride, silicon-carbon-oxynitride, combination thereof, or any other type of dielectric material(s), and may be deposited using, e.g., a conformal deposition process and subsequent etching back to remove excess spacer materials on the sidewalls of the stack 110′ and on the top surfaces of the semiconductor substrate 102. In some embodiments, the inner sidewall spacers 126 are formed of a material different from the sidewall spacer layer 122. The sidewall spacer layer 122 may serve as an etch mask during the removal of the excess spacer materials, and thus the outer sidewalls of the sidewall spacer layer 122 may be substantially aligned with outer sidewalls of the underlying second semiconductor layers 106 and outer sidewalls of the inner sidewall spacers 126.

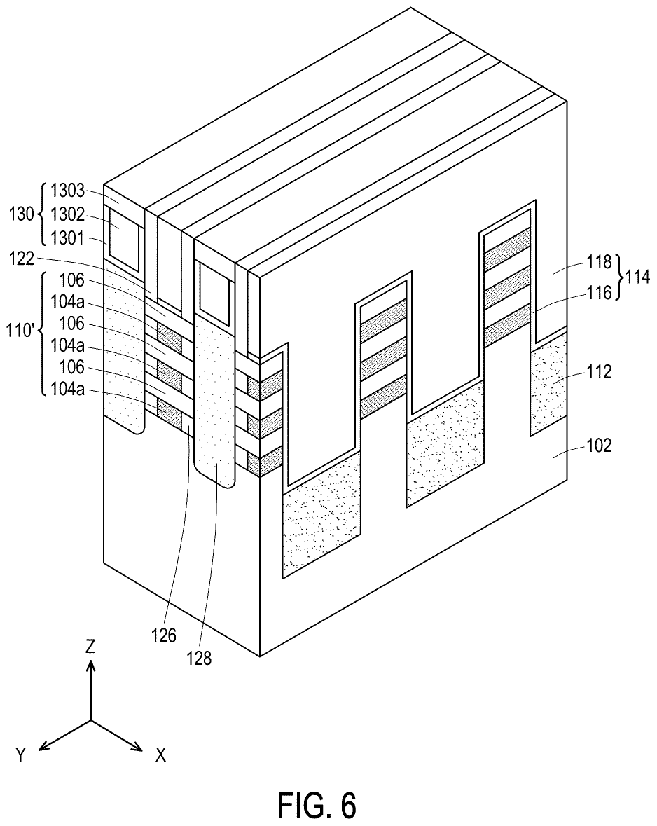

Referring to FIG. 6 and with reference to FIG. 5, epitaxial structures 128 may be formed in the recesses 102R. The epitaxial structures 128 may be coupled to the outer sidewalls of the second semiconductor layers 106 and the inner sidewall spacers 126. The respective epitaxial structure 128 may include a crystalline semiconductor material such as silicon germanium, indium arsenide, indium gallium arsenide, indium antimonide, germanium arsenide, germanium antimonide, indium aluminum phosphide, indium phosphide, any other suitable material, or combinations thereof. The epitaxial structures 128 may be doped with conductive dopants to form S/D regions. It should be noted that S/D region(s) may refer to a source or a drain, individually or collectively dependent upon the context. In addition, the terms “epitaxial structures” and “S/D regions” may be used interchangeably herein. In some embodiments, the epitaxial structures 128 are doped with different types of dopants. As shown in FIG. 6, one of the epitaxial structures 128 is configured for an n-type FET, and the other one of the epitaxial structures 128 is configured for a p-type FET. In alternative embodiments, the epitaxial structures 128 are doped with the same type of dopants (e.g., p-type dopants or n-type dopants) and configured for the same type of FET.

With continued reference to FIG. 6, an interlayer dielectric (ILD) structure 130 may be formed over the epitaxial structures 128. For example, the ILD structure 130 includes an etch stop layer 1301 (e.g., contact etch stop layer (CESL)) lining the sidewalls of the sidewall spacer layer 122 and the top surfaces of the epitaxial structures 128, a first dielectric layer 1302 disposed over the epitaxial structures 128 and wrapped around by the etch stop layer 1301, and a second dielectric layer 1303 overlying the first dielectric layer 1302 and laterally covered by the etch stop layer 1301. In some embodiments, the etch stop layer 1301 has a different material then the material(s) of the first dielectric layer 1302 and/or the second dielectric layer 1303. The etch stop layer 1301 may include a dielectric material (e.g., silicon nitride, silicon oxide, silicon oxynitride, or the like). For example, the etch stop layer 1301 may have a different etch rate than the material of the first dielectric layer 1302 and the material of the second dielectric layer 1303. The first dielectric layer 1302 and the second dielectric layer 1303 may be formed of a dielectric material including phosphosilicate glass (PSG), borosilicate glass (BSG), boron-doped phosphosilicate glass (BPSG), undoped silicate glass (USG), or the like. In some embodiments, a planarization process (e.g., chemical mechanical polishing (CMP), grinding, etching back, combinations thereof, or the like) is performed on the ILD structure 130. For example, the mask layer 120 (labeled in FIG. 5) and a portion of the ILD materials laterally adjoining the mask layer 120 are removed after the planarization process. The dummy gate structure 114 may be accessibly exposed after the planarization process.

Referring to FIG. 7A and FIG. 7B and with reference to FIG. 6, a removal process may be performed to remove a portion of the dummy gate structure 114, so as to form a trench 114T. The trench 114T has a width W1 along X direction. The width W1 is in a range of 8 nm to 20 nm, for example. The trench 114T may be disposed adjacent to the sidewall spacer layer 122 and the ILD structure 130 and extend along Y direction. The removal process may be performed to remove portions of the dummy gate layer 118 until the dummy dielectric layer 116 is exposed. In other words, the dummy dielectric layer 116 may be used as an etch stop layer during the partial removal of the dummy gate layer 118. The removal process may include one or more etching steps. For example, the etching step(s) that selectively etch the dummy gate layer 118 at a faster rate than the sidewall spacer layer 122. During the step of removing the dummy gate layer 118, the epitaxial structures 128 may be protected by the ILD structure 130. In some embodiments, as shown in FIG. 7B, after the dummy gate structure 114 is partially removed, the dummy dielectric layer 116 is exposed and top surfaces of the dummy dielectric layer 116 and the remained dummy gate layer 118 are substantially coplanar. However, the disclosure is not limited thereto. In alternative embodiments, the top surface of the dummy gate layer 118 may be lower than the top surface of the dummy dielectric layer 116 and/or lower than a top surface of the topmost nanosheet (i.e., topmost second semiconductor layer 106).

Referring to FIG. 8A and FIG. 8B and with reference to FIG. 7A and FIG. 7B, a lining layer 132 is formed over the substrate 102. In some embodiments, the lining layer 132 is formed over exposed surfaces of the ILD structure 130, the sidewall spacer layer 122 and the dummy gate structure 114. For example, the lining layer 132 is conformally formed on the exposed surfaces of the sidewall spacer layer 122, the etch stop layer 1301, the second dielectric layer 1303, the dummy dielectric layer 116 and the dummy gate layer 118. The lining layer 132 is formed of a material which may be selectively removed with respect to the material of the dummy gate layer 118. The lining layer 132 may be or includes one or more materials of aluminum oxide (Al₂O₃), silicon oxide (SiOₓ), silicon nitride (SiN), silicon carbonnitride (SiCN), silicon oxycarbonnitride (SiOCN), silicon oxycarbide (SiOC), hafnium oxide (HfO₂), a low-temperature oxide, a combination thereof, and the like. The lining layer 132 may be formed by using physical vapor deposition (PVD), chemical vapor deposition (CVD), atomic layer deposition (ALD), sputtering, or other suitable techniques. The lining layer 132 may have a thickness in a range of about 1 nm and about 5 nm.

Referring to FIG. 9A and FIG. 9B and with reference to FIG. 8A and FIG. 8B, a photoresist 140 is formed over the lining layer 132. The photoresist 140 is formed on the lining layer 132 over the substrate 102. The photoresist 140 may be a multi-layer photoresist which includes a bottom layer, a middle layer and a photoresist layer. The bottom layer may be a bottom anti-reflective coating (BARC) layer, an ashing removal dielectric (ARD) layer (such as amorphous carbon), a carbon layer, a hydrogen layer, a polymer layer, and the like. The middle layer may include a silicon oxide deposited using a vapor deposition technique or a spin-on technique, a nitride (such as silicon nitride), an oxynitride (such as silicon oxynitride), an oxide (such as silicon oxide), or the like. The photoresist layer may be formed of a photosensitive material, which includes organic materials, and may be a positive photosensitive material or a negative photosensitive material. The photoresist 140 may be blanket deposited sequentially using a vapor deposition technique or a spin-on technique. The photoresist 140 includes a trench 140T. The trench 140T extends along X direction, for example.

Then, the lining layer 132 is patterned by using the photoresist 140 as a mask, to form a trench 132T. In some embodiments, the trench 132T extends along X direction, and exposes the ILD structure 130, the sidewall spacer layer 122 and the dummy gate structure 114 therebeneath. For example, the trench 140T, 132T exposes the sidewall spacer layer 122, the second dielectric layer 1303 and the dummy gate layer 118. The trench 132T has a width W10 along Y direction, for example. The width W10 is in a range of 10 nm to 40 nm, for example. The width W10 may be substantially the same as the width of the trench 140T. For example, as shown in FIG. 9A and FIG. 9B, sidewalls of the trench 132T are substantially aligned with sidewalls of the trench 140T. However, the disclosure is not limited thereto. In alternative embodiments, the trench 132T is slightly larger than the trench 140T. In some embodiments, by the forming and the patterning of the lining layer 132, as shown in FIG. 9C, in a cut gate region CGR which is a crossover region of the trench 114T and the trench 132T, the trench 114T has the width W1. As shown in FIG. 9D, in other regions (e.g., region OR), the trench 114T with the lining layer 132 thereon has a width W2 smaller than the width W1. A difference between the width W1 and the width W2 is about twice of the thickness of the lining layer 132. Thus, a critical dimension (CD) difference may be obtained.

Referring to FIG. 10A and FIG. 10B and with reference to FIG. 9A and FIG. 9B, the photoresist 140 is removed, and a gap-filling dielectric layer 142 is formed on the lining layer 132 over the substrate 102. The gap-filling dielectric layer 142 is formed of a material which may be selectively removed with respect to the material of the dummy gate layer 118. The gap-filling dielectric layer 142 and the lining layer 132 have the same or different materials. The gap-filling dielectric layer 142 may be or includes one or more materials of aluminum oxide (Al₂O₃), silicon oxide (SiOₓ), silicon nitride (SiN), silicon carbonnitride (SiCN), silicon oxycarbonnitride (SiOCN), silicon oxycarbide (SiOC), hafnium oxide (HfO₂), a low-temperature oxide, a combination thereof, and the like. The gap-filling dielectric layer 142 may be formed by using physical vapor deposition (PVD), chemical vapor deposition (CVD), sputtering, or other suitable techniques. In some embodiments, the material of the gap-filling dielectric layer 142 and the lining layer 132 is aluminum oxide (Al₂O₃). The gap-filling dielectric layer 142 may have a thickness in a range of about 4 nm and about 10 nm.

Due to the critical dimension difference of the trench 114T in the cut gate region CGR and the regions (e.g., region OR) other than the cut gate region CGR (shown in FIG. 10A), a recess 142S is formed in the trench 114T in the cut gate region CGR (shown in FIG. 10B) while the gap-filling dielectric layer 142 fills up the trench 114T in the other regions (e.g., region OR). For example, as shown in FIG. 10B, the materials of the gap-filling dielectric layer 142 above opposite sides of the trench 132T in the cut gate region CGR are not merged, and thus the recess 142S is formed.

Referring to FIG. 11A to FIG. 12B and with reference to FIG. 10A and FIG. 10B, portions of the gap-filling dielectric layer 142, the lining layer 132 and the dummy gate layer 118 are removed, to form an opening 144 in the cut gate region CGR. First, as shown in FIG. 11A and FIG. 11B and with reference to FIG. 10A and FIG. 10B, portions of the gap-filling dielectric layer 142 and the lining layer 132 are removed by a first etching process, to form a first opening 144a. The first etching process includes using dry etching and/or wet etching, for example. The first etching process may be an isotropic etching process or the like. In some embodiments, as shown in FIG. 11A and with reference to FIG. 10A, in the regions (e.g., region OR) other than the cut gate region CGR, the first etching process removes portions of the gap-filling dielectric layer 142 and the lining layer 132 above the sidewall spacer layer 122 and the ILD structure 130 (e.g., the etch stop layer 1301 and the second dielectric layer 1303), so that top surfaces of the sidewall spacer layer 122 and the ILD structure 130 are exposed. For example, top surfaces of the gap-filling dielectric layer 142 and the lining layer 132 remained in the trench 114T are substantially coplanar with the top surfaces of the sidewall spacer layer 122 and the ILD structure 130. As shown in FIG. 11, the top surfaces of the gap-filling dielectric layer 142 and the lining layer 132 remained in the trench 114T may be slightly lower than the top surfaces of the sidewall spacer layer 122 and the ILD structure 130.

In some embodiments, as shown in FIG. 11B and with reference to FIG. 10B, in the cut gate region CGR, the first etching process removes portions of the gap-filling dielectric layer 142 aside the recess 142S, to form the first opening 144a exposing the dummy gate layer 118. The first opening 144a has a width W11 along Y direction and a width W12 along X direction (shown in FIG. 12C), for example. The width W12 of the first opening 144a is substantially equal to the width W1 of the trench 114T of FIG. 7A, for example. The width W12 may be in a range of 8 nm to 20 nm. The width W11 may be larger than or substantially the same as the width W12. The width W11 is in a range of 10 nm to 40 nm, for example. In some embodiments, the width W11 is different from or substantially the same as the width W10 of the trench 132T (shown in FIG. 10B). For example, when the first etching process also removes a portion of the lining layer 132 aside the trench 132T of FIG. 10B or further removes portions of the gap-filling dielectric layer 142 and the dummy gate layer 118, the width W11 of the first opening 144a is larger than the width W10 of the trench 132T. On contrary, if the first etching process does not remove the lining layer 132 aside the trench 132T of FIG. 10B, the first opening 144a is substantially the same as the width W10 of the trench 132T. During the formation of the first opening 144a, the sidewall spacer layer 122 and the ILD structure 130 may remain substantially intact due to the etch selectivity between the lining layer 132 and the sidewall spacer layer 122 and the ILD structure 130. The first etching process may stop on a top of the dummy gate layer 118 due to the etching selectivity between the gap-filling dielectric layer 142 and the lining layer 132 and the dummy gate layer 118.

Then, as shown in FIG. 12A and FIG. 12B and with reference to FIG. 11A and FIG. 11B, the exposed dummy gate layer 118 is removed through the first opening 144a by a second etching process, to form a second opening 144b. The second opening 144b has a width W21 along Y direction. The width W21 is in a range of 30 nm to 50 nm, for example. The second opening 144b is connected to and communicated with the first opening 144a. The first opening 144a and the second opening 144b are collectively referred to as an opening 144. The first opening 144a is disposed in the gap-filling dielectric layer 142 and the lining layer 132, and the second opening 144b is disposed between adjacent stacks 110′ of the etched first semiconductor layers 104a and the second semiconductor layers 106. The second etching process includes using dry etching and/or wet etching, for example. The second etching process may be an isotropic etching process or the like. The second etching process uses an etchant having an etching selectivity between the dummy gate layer 118 and the gap-filling dielectric layer 142 and the lining layer 132. For example, during the second etching process, the lining layer 132 having an etch selectivity with respect to the dummy gate layer 118 may use as a stop layer, and thus the second etching process would not further remove the gap-filling dielectric layer 142 and the lining layer 132 aside the first opening 144a. Thus, the profile and the width W11 of the first opening 144a may remain, and the profile and the width W21 of the second opening 144b may be well controlled. For example, an upper profile 144c (e.g., flat shoulder) of the second opening 144b may remain intact during the second etching process. In other words, the profile of the opening 144 may be well controlled. The etchant also has an etching selectivity between the dummy gate layer 118 and the dummy dielectric layer 116, and the dummy gate layer 118 (e.g., on a surface of the stack 110′) may be covered by the lining layer 132. Thus, the dummy dielectric layers 116 may be not removed during the second etching process. Furthermore, since other regions (e.g., region OR) than the cut gate region CGR are fully covered by the gap-filling dielectric layer 142 and the lining layer 132, the epitaxial structures 128, the sidewall spacer layer 122 and the ILD structure 130 may remain substantially intact during the formation of the opening 144. Thus, the loss and/or damage of the sidewall spacer layer 122 and the ILD structure 130 may be also avoided.

In some embodiments, as shown in FIG. 12A and FIG. 12B, the opening 144 is bottle-like. From a top view, as shown in FIG. 12C, the first opening 144a has a circle-like shape such as an oblong, an ellipse, an oval, and a circle or a rectangular shape while the second opening 144b has a rectangular-like shape (not shown). For example, the first opening 144a has opposing sidewalls 144s1 adjacent to the gap-filling dielectric layer 142 and the lining layer 132 and opposing sidewalls 144s2 adjacent to the sidewall spacer layer 122. The sidewalls 144s1 are curved sidewalls (e.g., convex sidewalls) and the sidewalls 144s2 are straight sidewalls, for example. However, the disclosure is not limited thereto. Each of the sidewalls 144s1, 144s2 is straight, concave or convex sidewall. The first opening 144a has the largest width W11 along Y direction and the largest width W12 along X direction. In some embodiments, the largest width W11 of the first opening 144a along Y direction is smaller than the width W21 of the second opening 144b. In some embodiments, the largest width W11 of the first opening 144a along Y direction is at a central line of the first opening 144a, and the smallest width W11′ of the first opening 144a along Y direction is at an edge of the first opening 144a. The largest width W11 may be also the largest distance between the opposing sidewalls 144s1 along Y direction. The smallest width W11′ may be also the smallest distance between the opposing sidewalls 144s1 along Y direction and also a width of the sidewall 144s2 of the first opening 144a along Y direction. The smallest width W11′ is in a range of 10 nm to 40 nm, for example. The largest width W12 of the first opening 144a along X direction is the largest distance between the opposing sidewalls 144s2. In some embodiments, the sidewall 144s2 is substantially flush with the inner sidewall of the sidewall spacer layer 122. The first opening 144a may have a constant dimension from the top to bottom, and the second opening 144b may also have a constant dimension from the top to bottom. As shown in FIG. 12B, in a cross-sectional view, the opposing sidewalls 144s1 of the first opening 144a are substantially parallel to each other, and the opposing sidewalls 144s3 of the second opening 144b are substantially parallel to each other. However, the disclosure is not limited thereto. In alternative embodiments, the opening 144 may have other suitable shape such as a big-headed shape.

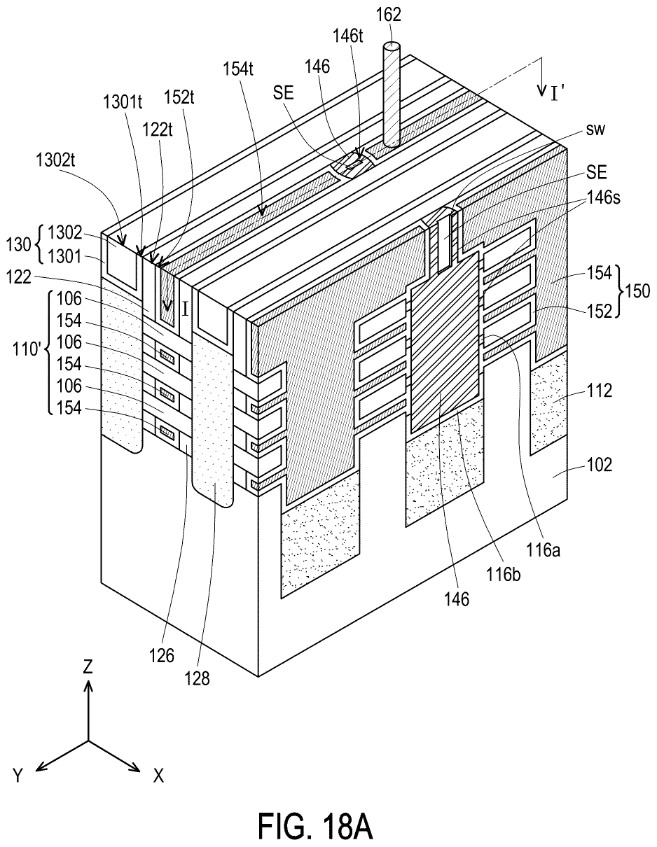

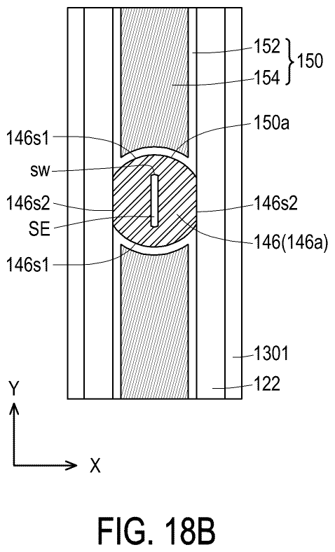

Referring to FIG. 13A and FIG. 13B and with reference to FIG. 12A and FIG. 12B, a wall structure 146 is formed in the opening 144 in the cut gate region CGR. The wall structure 146 includes a material having an etching selectivity with respect to the materials of the gap-filling dielectric layer 142, the lining layer 132 and the dummy gate layer 118. The wall structure 146 may include silicon nitride, silicon oxide, silicon carbo-nitride, silicon oxynitride, silicon oxy carbo-nitride, or the like, and may be formed by using physical vapor deposition (PVD), chemical vapor deposition (CVD), atomic layer deposition (ALD), sputtering, or other suitable techniques. In some embodiments, the wall structure 146 is void-free or seam-free. In alternative embodiments, as shown in FIG. 18A and FIG. 18B, due to the profile of the opening 144, during the formation of the wall structure 146, a void or seam SE is formed in the wall structure 146.

Referring to FIG. 14A and FIG. 14B and with reference to FIG. 13A and FIG. 13B, the remained gap-filling dielectric layer 142, the remained lining layer 132 and the dummy gate structures 114 are removed, to form a recess 142R. For example, the etching step(s) that selectively etch the remained gap-filling dielectric layer 142, the remained lining layer 132 and the remained dummy gate layer 118 at a faster rate than the sidewall spacer layer 122 and the ILD structure 130 is performed. The removal process includes using dry etching and/or wet etching, for example. In some embodiments, during this step, the dummy dielectric layer 116 may be remained or partially removed.

Referring to FIG. 15A and FIG. 15B and with reference to FIG. 14A and FIG. 14B, the etched first semiconductor layers 104a are removed by etching (e.g., isotropic etching or the like), to form recesses 104S. For example, using etchants which are selective to the materials of the etched first semiconductor layers 104a, while the second semiconductor layers 106, the sidewall spacer layer 122 and the ILD structure 130, and the inner sidewall spacers 126 may remain relatively un-etched as compared to the etched first semiconductor layers 104a. During the step of removing the etched first semiconductor layers 104a, the epitaxial structures 128 may be protected by the ILD structure 130. After the removal of the etched first semiconductor layers 104a, respective bottom and top surfaces of each second semiconductor layers 106 and the top surface of the semiconductor substrate 102 may be exposed by the recesses 104S. The removal process includes using dry etching and/or wet etching, for example. In some embodiments, before the removal of the etched first semiconductor layers 104a, the dummy dielectric layer 116 in the regions other than the cut gate region CGR and the dummy dielectric layer 116 over the stacks 110′ and the wall structure 146 may be entirely removed. For example, the isolation structure 112 in the region aside the cut gate region CGR is exposed. In some embodiments, as shown in FIG. 15A and FIG. 15B, during the removal of the etched first semiconductor layers 104a, the dummy dielectric layer 116 may be partially removed, and the remained dummy dielectric layer 116 forms dummy dielectric patterns (e.g., dummy dielectric patterns) 116a between the nanosheets 106 and the sidewall of the wall structure 146 (e.g., the second portion 146b of FIG. 17B) and a dummy dielectric layer (e.g., gate dielectric layer) 116b between the isolation structure 112 and the wall structure 146. The dummy dielectric patterns 116a are disposed corresponding to the nanosheets 106 and may have a height smaller than the height of the nanosheet 106. For example, the dummy dielectric patterns 116a are respectively aligned with the nanosheets 106, a top surface of the dummy dielectric patterns 116a is lower than a top surface of the nanosheet 106, and a bottom surface of the dummy dielectric patterns 116a is higher than a bottom surface of the nanosheet 106.

Referring to FIG. 16A and FIG. 16B and With Reference to FIG. 15A and FIG. 15B, a respective gate structure 150 may be formed around the second semiconductor layers 106 and fills the recesses 142R and 104S. The wall structure 146 is disposed between adjacent two gate structures 150 in Y direction, for example. The respective gate structure 150 may include a gate dielectric layer 152 and a gate metal layer 154 wrapping around each second semiconductor layer 106 with the gate dielectric layer 152 disposed therebetween, where the second semiconductor layers 106 (also referred to as semiconductor nanosheets or channel layers) function as channel regions. In some embodiments, the gate dielectric layer 152 is disposed between the wall structure 146 and the nanosheet (i.e., second semiconductor layer 106). The gate dielectric layer 152 may be a single high-k dielectric material or may include a stack of multiple high-k dielectric materials. Other suitable dielectric material(s) may be used to form the gate dielectric layer 152. The gate metal layer 154 may include a number of sections abutted to each other, each of the gate metal sections may extend not only a plan along X direction and Y direction but also along Z direction. The gate metal layer 154 may include a stack of multiple metal materials. For example, one or more work function sublayers are interposed between the gate dielectric layer 152 and the gate metal layer 154, wherein the work function sublayers may be formed separately for the n-type FET and the p-type FET which may use different metal layers. In alternative embodiments, the respective gate structure 150 further includes an interfacial layer (not shown) formed between each second semiconductor layer 106 and the gate dielectric layer 152 and between the semiconductor substrate 102 and the bottommost gate dielectric layer 152. During the formation of the gate structure 150, portions of the wall structure 146, the ILD structure 130 and the sidewall spacer layer 122 may be also removed. For example, as shown in FIG. 16A and FIG. 16B, during the formation of the gate structure 150, the second dielectric layer 1303 and portions of the wall structure 146, the etch stop layer 1301, the first dielectric layer 1302 and the sidewall spacer layer 122 are removed. Thus, after the formation of the gate structure 150, top surfaces of the gate structure 150, the wall structure 146 and the ILD structure 130 and the sidewall spacer layer 122 may be substantially coplanar. For example, top surfaces 152t, 154t of the gate dielectric layer 152 and the gate metal layer 154 are substantially coplanar with top surfaces 146t, 1301t, 1302t, 122t of the wall structure 146, the etch stop layer 1301, the first dielectric layer 1302 and the sidewall spacer layer 122.

In some embodiments, as shown in the enlarged view of FIG. 16B, the gate dielectric layer 152 includes a high-k dielectric layer 152a and an interfacial layer 152b between the nanosheet 106 and the high-k dielectric layer 152a. For example, the interfacial layer 152b surrounds the nanosheets 106, the dummy dielectric patterns 116a and the wall structure 146. The high-k dielectric layer 152a surrounds the interfacial layer 152b. However, the disclosure is not limited thereto. In alternative embodiments in which the dummy dielectric pattern 116a is absent, as shown in FIG. 16C, the interfacial layer 152b surrounds the nanosheets 106, and the high-k dielectric layer 152a surrounding the interfacial layer 152b and the high-k dielectric layer 152a surrounding the wall structure 146 may be merged between the nanosheet 106 and the wall structure 146.

Referring to FIG. 17A and FIG. 17B and with reference to FIG. 16A and FIG. 16B, gate contacts 162 are formed in an ILD structure 160 over the gate structures 150. The gate contact 162 is disposed on and electrically connected to the respective gate structure 150. For example, the gate contact 162 is disposed adjacent to the wall structure 146.

In some embodiments, as shown in FIG. 17A and FIG. 17B, the wall structure 146 is bottle-like. The wall structure 146 is disposed between the gate structures 150 along Y direction and disposed between the sidewall spacer layer 122 along X direction. For example, the wall structure 146 has a first portion 146a and a second portion 146b. The second portion 146b is physically connected to and in direct contact with the first portion 146a, for example. The first portion 146a may be also referred to as a head portion, and the second portion 146b may be also referred to as a body portion. A surface (e.g., top surface) of the second portion 146b is also referred to as a shoulder portion 146c. In some embodiments, an entirety of the shoulder portion 146c of the wall structure 146 is substantially flat and at substantially the same height. In some embodiments, a top surface of the shoulder portion 146c is disposed at substantially the same height as an interface 146t′ between the first and second portions 146a and 146b and a top surface 106t of the topmost nanosheet (i.e., topmost second semiconductor layer 106). For example, as shown in FIG. 17B, the shoulder portion 146c is substantially coplanar with the top surface 106t of the topmost nanosheet (i.e., topmost second semiconductor layer 106). Particularly, the shoulder portion 146c is substantially coplanar with the top surface of the gate dielectric layer 152 on the topmost nanosheet (i.e., topmost second semiconductor layer 106). However, the disclosure is not limited thereto. The shoulder portion 146c may be disposed a height higher than or lower than the topmost nanosheet, and a distance between the shoulder portion 146c and the top surface 106t of the topmost nanosheet is less than 20 nm.

The first portion 146a is a top portion and the second portion 16b is a bottom portion, for example. From a top view, as shown in FIG. 17E, the first portion 146a has a circle-like shape such as a circle, an ellipse and an oval or a rectangular shape while the second portion 146b has a rectangular-like shape (not shown). For example, the first portion 146a has opposing sidewalls 146s1 facing/adjacent to the gate structures 150 (e.g., gate dielectric layer 152) and sidewalls 146s2 facing/adjacent to the sidewall spacer layers 122. In some embodiments, the sidewalls 146s1 are in direct contact with the gate structures 150 (e.g., gate dielectric layer 152), and the sidewalls 146s2 are in direct contact with the sidewall spacer layers 122. The sidewalls 146s1 are curved sidewalls (e.g., convex sidewalls) and the sidewalls 146s2 are straight sidewalls, for example. In some embodiments, the sidewalls 146s1 are protruded into the gate structures 150 (e.g., the gate dielectric layer 152). However, the disclosure is not limited thereto. Each of the sidewalls 146s1, 146s2 is straight, concave or convex sidewall. In some embodiments, a largest width W11 of the first portion 146a along Y direction is smaller than a width W21 of the second portion 146b. In some embodiments, the largest width W11 of the first portion 146a along Y direction is at a central line of the first portion 146a, and the smallest width W11′ of the first portion 146a along Y direction is at an edge of the first portion 146a. The largest width W11 may be also the largest distance between the opposing sidewalls 146s1 along Y direction. The smallest width W11′ may be also the smallest distance between the opposing sidewalls 146s1 along Y direction and also a width of the sidewall 146s2 of the first portion 146a along Y direction. The width W11′ is in a range of 10 nm to 40 nm, for example. The largest width W12 of the first portion 146a along X direction is the largest distance between the opposing sidewalls 146s2. The largest width W12 of the first portion 146a is substantially equal to a width of the gate structure 150. The largest width W12 is in a range of 8 nm to 20 nm, for example. In some embodiments, the opposing sidewalls 146s2 are substantially flush with the opposing sidewalls 150s of the gate structure 150 (e.g., opposing sidewalls of the gate dielectric layer 152) respectively and substantially flush with the opposing inner sidewalls 122s of the sidewall spacer layers 122 respectively. The first portion 146a may have a constant dimension from the top to bottom, and the second portion 146b may also have a constant dimension from the top to bottom. As shown in FIG. 17B, in a cross-sectional view, the opposing sidewalls 146s1 of the first portion 146a are substantially parallel to each other, and the opposing sidewalls 146s3 of the second portion 146b are substantially parallel to each other.

In some embodiments, from a top view, as shown in FIG. 17E, the gate structure 150 has a concave end portion 150a facing the wall structure 146 due to the shape of the wall structure 146. For example, the gate structure 150 is inward from an end of the wall structure 146. In some embodiments, since the gate structure 150 is disposed between two adjacent wall structures 146, the gate structure 150 has opposing concave end portions 150a. In some embodiments, the sidewall spacer layers 122 are disposed at opposite sides of the gate structure 150 and opposite sides of the wall structure 146, and the sidewall spacer layers 122 continuously extend along the gate structure 150 and the wall structure 146.

In some embodiments, as mentioned above, the location of the opening 144 for the wall structure 146 is well controlled, and thus the formed wall structure 146 would not protrude into the ILD structure 130, the epitaxial structures 128 and/or the sidewall spacer layer 122. As shown in FIG. 17C, the ILD structure 130 and the epitaxial structures 128 therebelow remain substantially intact after the formation of the wall structure 146, and the ILD structure 130 and the epitaxial structures 128 are physically separated from the wall structure 146. In other words, the loss and/or damage of the ILD structure 130 and the epitaxial structures 128 may be avoided. Similarly, as shown in FIG. 17D, the wall structure 146 has a constant width between the opposing sidewall spacer layers 122 without protruding into the opposing sidewall spacer layers 122. Thus, the loss and/or damage of the sidewall spacer layer 122 may be avoided.

In some embodiments, as shown in FIG. 17A and FIG. 17G, a cut metal gate 170 may be formed to cut the gate structure 150. The cut metal gate 170 may extends along X direction beyond the sidewalls of the sidewall spacer layer 122. For example, as shown in FIG. 17F, top portions of the sidewall spacer layer 122 and the ILD structure 130 may be removed during the formation of the cut metal gate 170, and a top portion of the cut metal gate 170 is formed. The top portion of the cut metal gate 170 is bowl-shaped, for example. The top portion of the cut metal gate 170 may have a width larger than the width W1 of the wall structure 146 (also the width W1 of the gate structure 150). In some embodiments, element 180 shows oxide definition (OD) region. The oxide definition (OD) region 180 may be disposed between the wall structure 146 and the cut metal gate 170. However, the disclosure is not limited thereto. The cut metal gate 170 may be omitted.

In an embodiment, if the wall structure has an undesired profile (e.g., a head portion of the wall structure does not have a desired width), a trimming process is further performed on the wall structure to modulate the profile. In such embodiment, a void or seam formed in the formation of the wall structure may be exposed at the sidewall of the wall structure during the trimming process. Thus, the etchant or the like using in the subsequent process may leakage into the wall structure through the void or seam, which causes the damage to the profile of the wall structure and also affects the isolation between the adjacent gate structures. On contrary, in some embodiments, since the profile of the opening 144 for the wall structure 146 is well controlled, the wall structure 146 formed in the opening 144 also has a desired profile (e.g., a desired width of the first portion 146a). Thus, an additional trimming process 146 may be not required. Accordingly, in some embodiments, as shown in FIG. 18A and FIG. 18B, even if the void or seam SE is formed during the formation of the wall structure 146, the sidewall sw of the void or seam SE is surrounded by and embedded in the material of the wall structure 146 without being exposed. For example, the void or seam SE is not be disposed at the sidewall 146s of the wall structure 146. Thus, in some embodiments, the profile of the wall structure 146 may be maintained and the current leakage issue may be avoided. It is noted that although the void or seam SE is illustrated as being extended from an interface of the first and second portions 146a, 146b to the top surface 146t of the wall structure 146. However, the disclosure is not limited thereto. The void or seam SE may be formed at any position of the wall structure 146 as long as the sidewalls sw of the void or seam SE are not exposed at the sidewalls 146s of the wall structure 146. Furthermore, the void or seam SE may be entirely embedded in the wall structure 146 without being exposed at the top surface 146t of the wall structure 146.

Furthermore, in an embodiment in which the wall structure has a shoulder portion at different heights (for example, the shoulder portion is protruded towards the landing position of the gate contact), the gate contact may be landed on the wall structure rather than the gate electrode. In such embodiments, there may be a gate contact landing issue. On contrary, in some embodiments, since the wall structure 146 has a desired profile such as the shoulder portion 146c at substantially the same height and being flat, even if the gate contact 162 is slightly misaligned, the gate contact 162 may be still landed on the gate structure 150. Thus, the connection between the gate contact and the gate structure may be ensured, and the reliability and the yield of the semiconductor device may be improved.

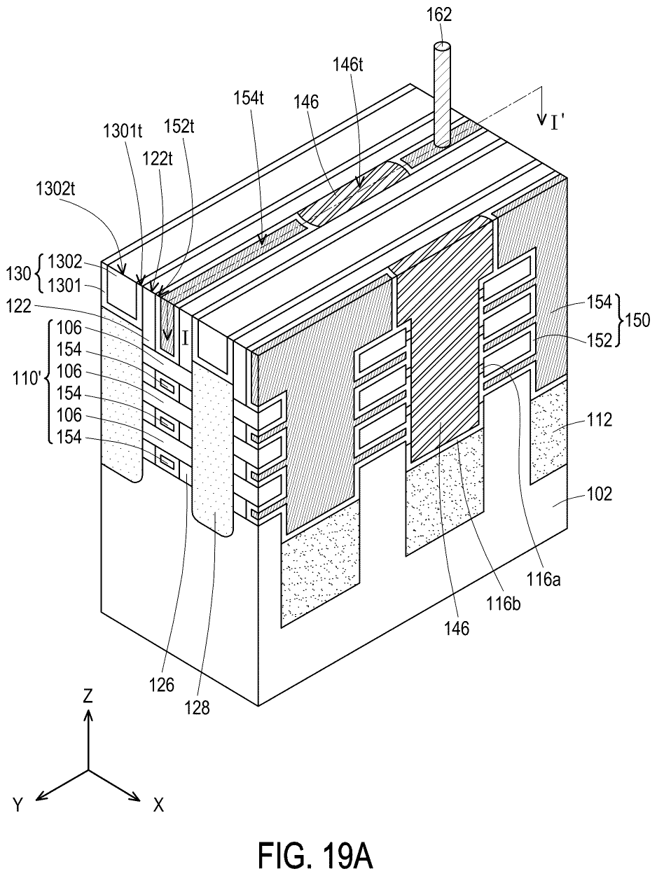

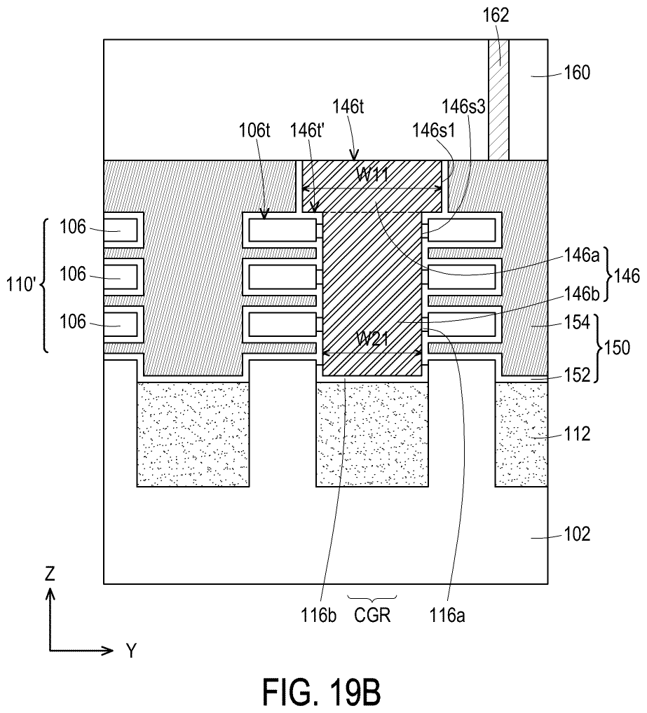

In some embodiments, the first portion 146a of the wall structure 146 is smaller than the second portion 146b. However, the disclosure is not limited thereto. In alternative embodiments, the wall structure 146 may have other suitable shape such as a big-headed shape as long as there is no landing issue of the gate contact. For example, as shown in FIG. 19A and FIG. 19B, the first portion 146a of the wall structure 146 has the width W11 larger than the width W21 of the second portion 146b along Y direction. In such embodiments, the gate contact 162 is disposed on and electrically connect to the respective gate structure 150, and the gate contact 162 is distant from the first portion 146a of the wall structure 146. The wall structure 146 is disposed between adjacent two gate structures 150 in Y direction. The interface 146t′ between the first and second portions 146a and 146b may be substantially coplanar with the top surface 106t of the topmost nanosheet (i.e., topmost second semiconductor layer 106). The wall structure 146 of FIG. 19A and FIG. 19B may be also formed by using the method of forming the wall structure 146 (e.g., FIG. 7A to FIG. 17E). In alternative embodiments (not shown), the first portion 146a of the wall structure 146 has the width W11 substantially the same as the width W21 of the second portion 146b along Y direction.

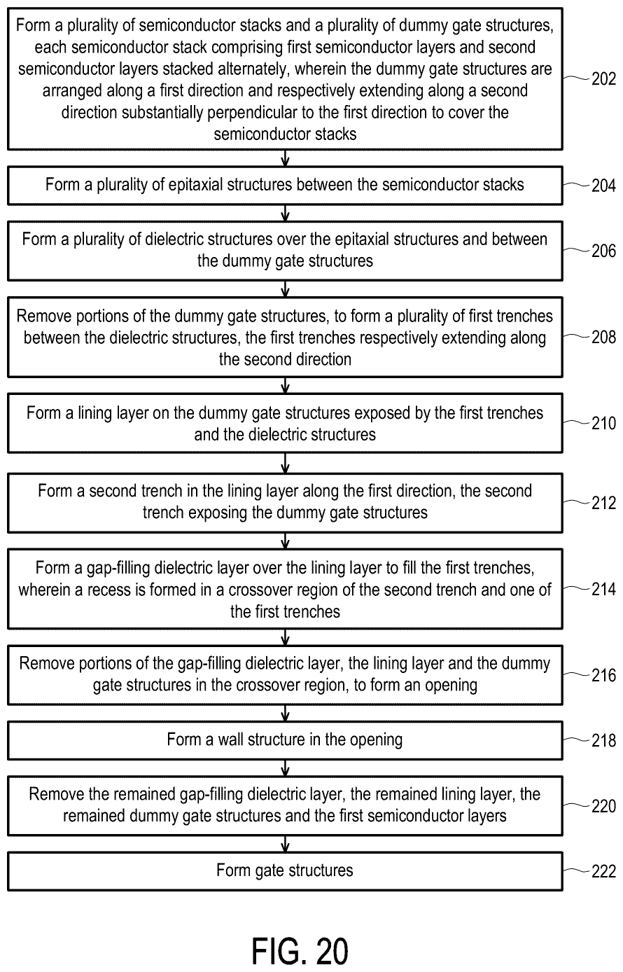

FIG. 20 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 202, a plurality of stacks and a plurality of dummy gate structures are formed, each stack including first semiconductor layers and second semiconductor layers stacked alternately, wherein the dummy gate structures are arranged along a first direction and respectively extending along a second direction substantially perpendicular to the first direction to cover the stacks. FIG. 1 to FIG. 5 illustrate views corresponding to some embodiments of act 202.

At act 204, a plurality of epitaxial structures are formed between the stacks. FIG. 6 illustrates a view corresponding to some embodiments of act 204.

At act 206, a plurality of dielectric structures over the epitaxial structures and between the dummy gate structures. FIG. 6 illustrates a view corresponding to some embodiments of act 206.

At act 208, portions of the dummy gate structures are removed, to form a plurality of first trenches between the dielectric structures, and the first trenches respectively extending along the second direction. FIG. 7A and FIG. 7B illustrate views corresponding to some embodiments of act 208.

At act 210, a lining layer is formed on the dummy gate structures exposed by the first trenches and the dielectric structures. FIG. 8A and FIG. 8B illustrate views corresponding to some embodiments of act 210.

At act 212, a second trench is formed in the lining layer along the first direction, the second trench exposing the dummy gate structures. FIG. 9A to FIG. 9D illustrate views corresponding to some embodiments of act 212.

At act 214, a gap-filling dielectric layer is formed over the lining layer to fill the first trenches, wherein a recess is formed in a crossover region of the second trench and one of the first trenches. FIG. 10A and FIG. 10B illustrate views corresponding to some embodiments of act 214.

At act 216, portions of the gap-filling dielectric layer, the lining layer and the dummy gate structures in the crossover region are removed, to form an opening. FIG. 11A to FIG. 12C illustrate views corresponding to some embodiments of act 216.

At act 218, a wall structure is formed in the opening. FIG. 13A and FIG. 13B illustrate views corresponding to some embodiments of act 218.

At act 220, the remained gap-filling dielectric layer, the remained lining layer, the remained dummy gate structures and the first semiconductor layers are removed. FIG. 14A to FIG. 15B illustrate views corresponding to some embodiments of act 220.

At act 222, gate structures are formed. FIG. 16A and FIG. 16B illustrate views corresponding to some embodiments of act 222.

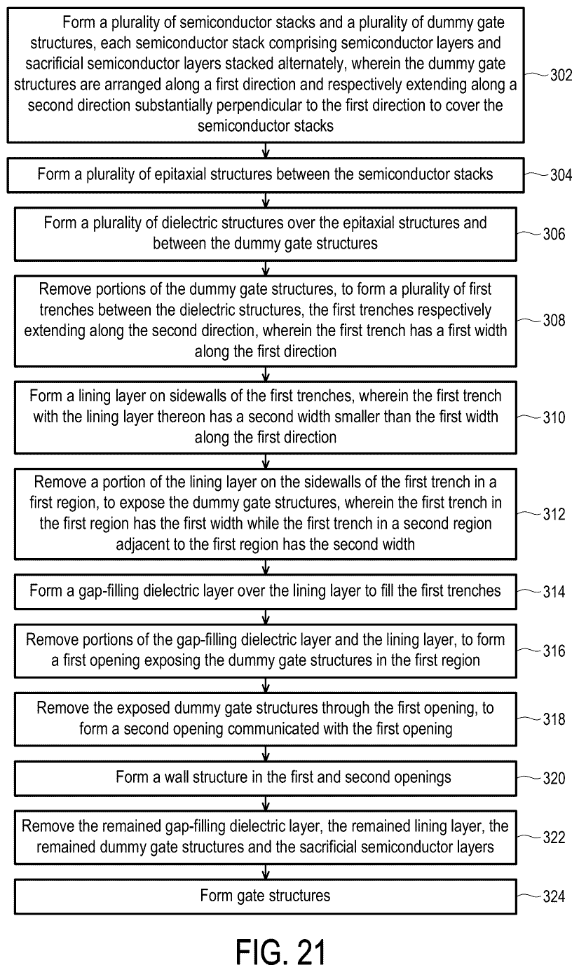

FIG. 21 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 302, a plurality of semiconductor stacks and a plurality of dummy gate structures are formed, each semiconductor stack including semiconductor layers and sacrificial semiconductor layers stacked alternately, wherein the dummy gate structures are arranged along a first direction and respectively extending along a second direction substantially perpendicular to the first direction to cover the semiconductor stacks. FIG. 1 to FIG. 5 illustrate views corresponding to some embodiments of act 302.

At act 304, a plurality of epitaxial structures are formed between the semiconductor stacks. FIG. 6 illustrates a view corresponding to some embodiments of act 304.

At act 306, a plurality of dielectric structures over the epitaxial structures and between the dummy gate structures. FIG. 6 illustrates a view corresponding to some embodiments of act 306.

At act 308, portions of the dummy gate structures are removed, to form a plurality of first trenches between the dielectric structures, and the first trenches respectively extending along the second direction, wherein the first trench has a first width along the first direction. FIG. 7A and FIG. 7B illustrate views corresponding to some embodiments of act 308.

At act 310, a lining layer is formed on sidewalls of the first trenches, wherein the first trench with the lining layer thereon has a second width smaller than the first width along the first direction. FIG. 8A and FIG. 8B illustrate views corresponding to some embodiments of act 310.

At act 312, a portion of the lining layer on the sidewalls of the first trench in a first region is removed, to expose the dummy gate structures, wherein the first trench in the first region has the first width while the first trench in a second region adjacent to the first region has the second width. FIG. 9A to FIG. 9D illustrate views corresponding to some embodiments of act 312.

At act 314, a gap-filling dielectric layer is formed over the lining layer to fill the first trenches. FIG. 10A and FIG. 10B illustrate views corresponding to some embodiments of act 314.

At act 316, portions of the gap-filling dielectric layer and the lining layer are removed, to form a first opening exposing the dummy gate structures in the first region. FIG. 11A and FIG. 11B illustrate views corresponding to some embodiments of act 316.

At act 318, the exposed dummy gate structures are removed through the first opening, to form a second opening communicated with the first opening. FIG. 12A to FIG. 12C illustrate views corresponding to some embodiments of act 318.

At act 320, a wall structure is formed in the first and second openings. FIG. 13A and FIG. 13B illustrate views corresponding to some embodiments of act 320.

At act 322, the remained gap-filling dielectric layer, the remained lining layer, the remained dummy gate structures and the sacrificial semiconductor layers are removed. FIG. 14A to FIG. 15B illustrate views corresponding to some embodiments of act 322.

At act 324, gate structures are formed. FIG. 16A and FIG. 16B illustrate views corresponding to some embodiments of act 324.

In accordance with an embodiment of the disclosure, a method of forming a semiconductor device includes the following steps. A plurality of semiconductor stacks and a plurality of dummy gate structures are formed, each semiconductor stack including first semiconductor layers and second semiconductor layers stacked alternately, wherein the dummy gate structures are arranged along a first direction and respectively extending along a second direction substantially perpendicular to the first direction to cover the semiconductor stacks. A plurality of epitaxial structures are formed between the semiconductor stacks. A plurality of dielectric structures are formed over the epitaxial structures and between the dummy gate structures. Portions of the dummy gate structures are removed, to form a plurality of first trenches between the dielectric structures, and the first trenches respectively extending along the second direction. A lining layer is formed on the dummy gate structures exposed by the first trenches and the dielectric structures. A second trench is formed in the lining layer along the first direction, the second trench exposing the dummy gate structures. A gap-filling dielectric layer is formed over the lining layer to fill the first trenches, wherein a recess is formed in a crossover region of the second trench and one of the first trenches. Portions of the gap-filling dielectric layer, the lining layer and the dummy gate structures in the crossover region are removed, to form an opening. A wall structure is formed in the opening. The remained dummy gate structures are replaced with gate structures.

In accordance with an embodiment of the disclosure, a method of forming a semiconductor device includes the following steps. A plurality of semiconductor stacks and a plurality of dummy gate structures are formed, each semiconductor stack including first semiconductor layers and second semiconductor layers stacked alternately, wherein the dummy gate structures are arranged along a first direction and respectively extending along a second direction substantially perpendicular to the first direction to cover the semiconductor stacks. A plurality of epitaxial structures are formed between the semiconductor stacks. A plurality of dielectric structures are formed over the epitaxial structures and between the dummy gate structures. Portions of the dummy gate structures are removed, to form a plurality of first trenches between the dielectric structures, and the first trenches respectively extending along the second direction, wherein the first trench has a first width along the first direction. A lining layer is formed on sidewalls of the first trenches, wherein the first trench with the lining layer thereon has a second width smaller than the first width along the first direction. A portion of the lining layer on the sidewalls of the first trench in a first region is removed, to expose the dummy gate structures, wherein the first trench in the first region has the first width while the first trench in a second region adjacent to the first region has the second width. A gap-filling dielectric layer is formed over the lining layer to fill the first trenches. Portions of the gap-filling dielectric layer and the lining layer are removed, to form a first opening exposing the dummy gate structures in the first region. The exposed dummy gate structures are removed through the first opening, to form a second opening communicated with the first opening. A wall structure is formed in the first and second openings. The remained dummy gate structures are replaced with gate structures.

In accordance with an embodiment of the disclosure, a semiconductor device includes a semiconductor substrate, a plurality of gate structures and a wall structure. The gate structures are disposed over the semiconductor substrate and respectively wrapping around a plurality of semiconductor layers. The wall structure is disposed between the gate structures and includes a first portion having a first width and a second portion having a second width different from the first width. The second portion is disposed between the first portion and the semiconductor substrate, wherein the first portion has a circle-like shape from a top view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a plurality of semiconductor stacks and a plurality of dummy gate structures, each semiconductor stack comprising first semiconductor layers and second semiconductor layers semiconductor stacked alternately, wherein the dummy gate structures are arranged along a first direction and respectively extending along a second direction substantially perpendicular to the first direction to cover the semiconductor stacks;
forming a plurality of epitaxial structures between the semiconductor stacks;
forming a plurality of dielectric structures over the epitaxial structures and between the dummy gate structures;
removing portions of the dummy gate structures, to form a plurality of first trenches between the dielectric structures, the first trenches respectively extending along the second direction;
forming a lining layer on the dummy gate structures exposed by the first trenches and the dielectric structures;
forming a second trench in the lining layer along the first direction, the second trench exposing the dummy gate structures;
forming a gap-filling dielectric layer over the lining layer to fill the first trenches, wherein a recess is formed in a crossover region of the second trench and one of the first trenches;
removing portions of the gap-filling dielectric layer, the lining layer and the dummy gate structures in the crossover region, to form an opening;
forming a wall structure in the opening;
removing the remained gap-filling dielectric layer, the remained lining layer, the remained dummy gate structures and the first semiconductor layers; and
forming gate structures.

2. The method of claim 1, wherein removing portions of the gap-filling dielectric layer, the lining layer and the dummy gate structures comprise:
removing the portions of the gap-filling dielectric layer and the lining layer to expose the dummy gate structures by a first etching process; and
removing the portions of the dummy gate structures by a second etching process.

3. The method of claim 2, wherein the first etching process stops on tops of the dummy gate structures.

4. The method of claim 2, wherein the second etching process uses an etchant having an etching selectivity between the dummy gate structures and the gap-filling dielectric layer and the lining layer.

5. The method of claim 1, wherein a material of the gap-filling dielectric layer is the same as a material of the lining layer.

6. The method of claim 1, wherein a material of the lining layer and the gap-filling dielectric layer comprises aluminum oxide, silicon oxide, silicon nitride or a combination thereof.

7. The method of claim 1, wherein removing the portions of the gap-filling dielectric layer and the lining layer comprises performing an isotropic etching process.

8. The method of claim 1, wherein the wall structure is disposed between the gate structures along the second direction and disposed between the dielectric structures along the first direction.

9. A method of forming a semiconductor device, comprising:
forming a plurality of semiconductor stacks and a plurality of dummy gate structures, each semiconductor stack comprising semiconductor layers and sacrificial semiconductor layers semiconductor stacked alternately, wherein the dummy gate structures are arranged along a first direction and respectively extending along a second direction substantially perpendicular to the first direction to cover the semiconductor stacks;
forming a plurality of epitaxial structures between the semiconductor stacks;
forming a plurality of dielectric structures over the epitaxial structures and between the dummy gate structures;
removing portions of the dummy gate structures, to form a plurality of first trenches between the dielectric structures, the first trenches respectively extending along the second direction, wherein the first trench has a first width along the first direction;
forming a lining layer on sidewalls of the first trenches, wherein the first trench with the lining layer thereon has a second width smaller than the first width along the first direction;
removing a portion of the lining layer on the sidewalls of the first trench in a first region, to expose the dummy gate structures, wherein the first trench in the first region has the first width while the first trench in a second region adjacent to the first region has the second width;
forming a gap-filling dielectric layer over the lining layer to fill the first trenches;
removing portions of the gap-filling dielectric layer and the lining layer, to form a first opening exposing the dummy gate structures in the first region;
removing the exposed dummy gate structures through the first opening, to form a second opening communicated with the first opening;
forming a wall structure in the first and second openings;
removing the remained gap-filling dielectric layer, the remained lining layer, the remained dummy gate structures and the sacrificial semiconductor layers; and
forming gate structures.

10. The method of claim 9, wherein after removing the portions of the gap-filling dielectric layer and the lining layer, a top surface of the gap-filling dielectric layer is substantially coplanar with top surfaces of the dielectric structures.

11. The method of claim 9, wherein removing the remained gap-filling dielectric layer, the remained lining layer, the remained dummy gate structures and the sacrificial semiconductor layers and forming the gate structures comprise:
removing the remained gap-filling dielectric layer, the remained lining layer, the remained dummy gate structures, to form a first recess;
removing the sacrificial semiconductor layers, to form second recesses; and
forming the gate structures in the first recess and the second recesses.

12. The method of claim 9, wherein the dummy gate structures comprise dummy dielectric layers and dummy gate layers, and removing the exposed dummy gate structures through the first opening comprises removing the exposed dummy gate layers without removing the dummy dielectric layers.

13. The method of claim 12, wherein during removing the exposed dummy gate layers, the lining layer covers the dummy dielectric layers disposed on the semiconductor stacks.

14. A semiconductor device, comprising:
a semiconductor substrate;
first and second gate structures over the semiconductor substrate, respectively wrapping around a plurality of semiconductor layers, wherein the first and second gate structures respectively extend in a first direction; and
a wall structure disposed between the first and second gate structures, comprising a first portion having a first width and a second portion having a second width different from the first width, the second portion being disposed between the first portion and the semiconductor substrate, wherein a first sidewall of the first portion of the wall structure is substantially flush with a first sidewall of the first gate structure in the first direction.

15. The semiconductor device of claim 14, wherein a second sidewall opposite to the first sidewall of the first portion of the wall structure is substantially flush with a second sidewall opposite to the first sidewall of the first gate structure in the first direction.

16. The semiconductor device of claim 14, wherein the first and second sidewalls of the first portion are substantially straight sidewalls, and third and fourth sidewalls of the first portion facing the first and second gate structures are curved sidewalls.

17. The semiconductor device of claim 16, further comprising sidewall spacer layers extending along the first and second sidewalls of the first gate structure and the first and second sidewalls of the first portion.

18. The semiconductor device of claim 14, wherein an interface of the first portion and the second portion is substantially coplanar with a topmost surface of the semiconductor layers.

19. The semiconductor device of claim 14, further comprising a plurality of dummy dielectric patterns on a sidewall of the second portion, wherein the dummy dielectric patterns are disposed corresponding to the semiconductor layers.

20. The semiconductor device of claim 19, wherein the first gate structure comprises a gate metal layer, a gate dielectric layer and an interfacial layer between the gate metal layer and the gate dielectric layer, and the interfacial layer physically connects the semiconductor layers and the dummy dielectric patterns.
